(19) United States
(12) Patent Application Publication
(10) Pub. No.: US 2010/0087944 A1
(43) Pub. Date: Apr. 8, 2010

(54) SEMICONDUCTOR MANUFACTURING APPARATUS, METHOD OF MANAGING APPARATUS OPERATION PARAMETERS, AND PROGRAM

(75) Inventors: Noriaki Kanaya, Tokyo (JP); Koki Asakawa, Koshi-shi (JP); Kiyohito Iijima, Nirasaki-shi (JP); Masayuki Hirose, Nirasaki-shi (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/519,847

(22) PCT Filed: Mar. 18, 2008
(86) PCT No.: PCT/JP2008/054928

§ 371 Date: Dec. 1, 2009

(30) Foreign Application Priority Data
Mar. 24, 2007 (JP) 2007-078013

(51) Int. Cl. H01L 21/02

(52) U.S. Cl. 700/103; 700/121

(57) ABSTRACT

A process information managing device including recipe storage units that store two or more recipes which comprise information about a process maintained by two or more control devices, and correspond to the two or more control devices, respectively, a receiving unit that receives process parameter information that is information about process parameters included in the two or more recipes, a recipe information obtaining unit that searches for a recipe in the recipe storage unit by using the process parameter information and obtains recipe information that is information about the found recipe, and an output unit that outputs the recipe information obtained by the recipe information obtaining unit makes it possible to easily determine the one or more recipes affecting a change in the process parameters.

### CROSS-REFERENCE TO RELATED PATENT APPLICATION

This application claims the benefit of Japanese Patent Application 2007-078013, filed on Mar. 24, 2007, in the Japanese Patent Office, the disclosure of which is incorporated herein in its entirety by reference.

### BACKGROUND OF THE INVENTION

1. Field of the Invention

The present invention relates to a semiconductor manufacturing apparatus for performing a semiconductor manufacturing process, a method of managing apparatus operation parameters, and a program.

2. Description of the Related Art

A conventional semiconductor manufacturing apparatus includes a multi-chamber processing system, an object conveying system, and a device control system including a storage device for storing apparatus operation parameters and supplying the apparatus operation parameters to machine control units (please refer to Page 1 and FIG. 1 of Japanese Laid-Open Patent Publication No. 2001-75628). These machine control units control the multi-chamber processing system and the object conveying system according to the apparatus operation parameters. The device control system stores the apparatus operation parameters for each prioritized level in the storage device. The prioritized levels include a standard level inherent to the apparatus and a special level inherent to a user. The device control system develops the apparatus operation parameters stored in the storage device in memories according to priorities of the apparatus operation parameters.

The conventional semiconductor manufacturing apparatus can restore the apparatus operation parameters to standard and set values when shipping the conventional semiconductor manufacturing apparatus even if the apparatus operation parameters are overwritten with customer operation parameters.

### SUMMARY OF THE INVENTION

The conventional semiconductor manufacturing apparatus does not have a structure in which two or more different users that log in to the conventional semiconductor manufacturing apparatus in two or more different modes can individually control the apparatus operation parameters, which causes problems when manufacturing a semiconductor by using the conventional semiconductor manufacturing apparatus.

For example, a service engineer changes one or more parameters including the apparatus operation parameters for maintenance or evaluation of a semiconductor manufacturing apparatus. In this case, the service engineer personally changes customer operation parameters used by customers to operate the conventional semiconductor manufacturing apparatus.

When the service engineer is necessarily required to restore the customer operation parameters after maintenance or evaluation has been performed on the conventional semiconductor manufacturing apparatus, if the service engineer does not perform the restoration, it is difficult to properly manufacture the semiconductor, which causes defects to occur.

Furthermore, if the customer operation parameters include several hundreds of thousands of parameters, it may be difficult or cumbersome to manage the customer operation parameters changed by the service engineer during maintenance or evaluation of the conventional semiconductor manufacturing apparatus.

According to an aspect of the present invention, there is provided a semiconductor manufacturing apparatus for performing a semiconductor manufacturing process, the apparatus comprising: an input receiving unit for receiving an input regarding login in a first mode, an input regarding login in a second mode, and an input regarding a change in apparatus operation parameters that comprise one or more parameters used to operate the semiconductor manufacturing apparatus; a customer operation parameter storage unit for storing customer operation parameters that comprise apparatus operation parameters that are changeable by an input of a user who logs in to the semiconductor manufacturing apparatus in the first mode; a service parameter storage unit for storing service parameters that comprise apparatus operation parameters that are changeable by an input of a user who logs in to the semiconductor manufacturing apparatus in the second mode; a login processing unit for, when the input receiving unit receives the input regarding login in the first mode, processing login to the semiconductor manufacturing apparatus in the first mode, and when the input receiving unit receives the input regarding login in the second mode, processing login to the semiconductor manufacturing apparatus in the second mode; a customer operation parameter changing unit for, when the input receiving unit receives the input regarding the change in the apparatus operation parameters from the user who logs in to the semiconductor manufacturing apparatus in the first mode, changing the customer operation parameters stored in the customer operation parameter storage unit; a service parameter changing unit for, when the input receiving unit receives the input regarding the change in the apparatus operation parameters from the user who logs in to the semiconductor manufacturing apparatus in the second mode, changing the service parameters stored in the service parameter storage unit; a processing unit for reading at least the customer operation parameters or the service parameters and performing an operation for executing the semiconductor manufacturing process according to the read parameters; a determining unit for comparing the customer operation parameters with the service parameters and determining whether the customer operation parameters and the service parameters are identical to each other; and an output unit for, if the determining unit determines that the customer operation parameters and the service parameters are different from each other, outputting comparison information indicating that the customer operation parameters and the service parameters are different from each other.

According to the above-mentioned construction, two or more different users that log in to the semiconductor manufacturing apparatus in two or more different modes may individually control apparatus operation parameters. For example, service parameters used by a service engineer may be managed separately from customer operation parameters. If the service parameters and the customer operation parameters are different from each other, such a difference may be brought to a service engineer's notice. As a result, for example, the service engineer can prevent the service parameters used to maintain or evaluate the semiconductor manufacturing apparatus from having a bad influence to manufacturing of a semiconductor.

The apparatus may further comprise: a default parameter storage unit for storing default parameters that comprise default apparatus operation parameters, wherein the processing unit reads at least the default parameters, the customer operation parameters, or the service parameters and performs the operation for executing the semiconductor manufacturing process according to the read parameters.

According to the above-mentioned construction, for example, service parameters used by a service engineer may be managed separately from default parameters or customer operation parameters. If the service parameters and the customer operation parameters are different from each other, such a difference may be brought to a service engineer's notice. As a result, for example, the service engineer can prevent the service parameters used to maintain or evaluate the semiconductor manufacturing apparatus from having a bad influence to manufacturing of a semiconductor.

The input receiving unit may further receive an instruction to output changed service parameters; and wherein, when the input receiving unit receives the instruction to output the changed service parameters, the output unit reads the service parameters changed by the service parameter changing unit from the service parameter storage unit and outputs the read changed service parameters, instead of outputting the comparison information.

According to the above-mentioned construction, a service engineer can easily identify service parameters that have been changed from customer operation parameters, thereby increasing efficiency in an operation of maintaining or evaluating the semiconductor manufacturing apparatus.

The comparison information may include the customer operation parameters and the service parameters.

According to the above-mentioned construction, a service engineer can easily identify a difference between service parameters and customer operation parameters.

The input receiving unit may further receive a complete change instruction to completely overwrite the service parameters with the customer operation parameters or an individual change instruction to individually overwrite the service parameters with the customer operation parameters, the apparatus further comprising: a service parameter reflecting unit for, when the input receiving unit receives the complete change instruction, completely overwriting the service parameters with the customer operation parameters, or when the input receiving unit receives the individual change instruction, individually overwriting parameters corresponding to the service parameters according to the corresponding individual change instruction with parameters corresponding to the customer operation parameters.

According to the above-mentioned construction, a result obtained by maintaining or evaluating the semiconductor manufacturing apparatus performed by a service engineer can be used to manufacture a customer's semiconductor.

The processing unit may: read the service parameters from the service parameter storage unit; for parameters that are not defined as the service parameters, read the corresponding customer operation parameters from the customer operation parameter storage unit; and perform the operation for executing the semiconductor manufacturing process according to the read parameters.

According to the above-mentioned construction, a semiconductor can be manufactured by properly using service parameters and customer operation parameters.

The processing unit may: read the service parameters from the service parameter storage unit; for parameters that are not defined as the service parameters, read the corresponding customer operation parameters from the customer operation parameters; for parameters that are not defined as the service parameters nor the customer operation parameters, read the corresponding default parameters from a default parameter storage unit; and perform the operation for executing the semiconductor manufacturing process according to the read parameters.

According to the above-mentioned construction, a semiconductor can be manufactured by properly using default parameters, service parameters, and customer operation parameters.

### BRIEF DESCRIPTION OF THE DRAWINGS

The above and other features and advantages of the present invention will become more apparent by describing in detail exemplary embodiments thereof with reference to the attached drawings in which:

FIG. 1 is a block diagram of a semiconductor manufacturing apparatus according to an embodiment of the present invention;

FIG. 2 illustrates a cluster tool device of the semiconductor manufacturing apparatus according to the embodiment of the present invention;

FIG. 3 is a block diagram of a processing unit of the semiconductor manufacturing apparatus according to the embodiment of the present invention;

FIG. 4 is a flowchart illustrating a process of operation of the semiconductor manufacturing apparatus according to the embodiment of the present invention;

FIG. 5 is a flowchart illustrating the operation of the semiconductor manufacturing apparatus according to the embodiment of the present invention;

FIG. 6 is a flowchart illustrating a process of changing apparatus operation parameters of the semiconductor manufacturing apparatus according to the embodiment of the present invention;

FIG. 7 is a flowchart illustrating a process of logging out of the semiconductor manufacturing apparatus according to the embodiment of the present invention;

FIG. 8 is a table used for managing the apparatus operation parameters according to the embodiment of the present invention;

FIG. 9 is a table used for managing default parameters according to the embodiment of the present invention;

FIG. 10 is a table used for managing users according to the embodiment of the present invention;

FIG. 11 shows an example of a display output according to the embodiment of the present invention;

FIG. 12 is a table showing customer operation parameters according to the embodiment of the present invention;

FIG. 13 is a table showing apparatus operation parameters according to the embodiment of the present invention;

FIG. 14 shows an example of a display output according to the embodiment of the present invention;

FIG. 15 is a table showing service parameters according to the embodiment of the present invention;

FIG. 16 is a table showing apparatus operation parameters according to the embodiment of the present invention;

FIG. 17 shows an example of a display output according to the embodiment of the present invention;

FIG. 18 shows an example of a display output according to the embodiment of the present invention;

FIG. 19 is a table showing customer operation parameters according to the embodiment of the present invention;

FIG. 20 is a table showing service parameters according to the embodiment of the present invention;

FIG. 21 is a table showing apparatus operation parameters according to the embodiment of the present invention;

FIG. 22 is a table showing customer operation parameters according to the embodiment of the present invention;

FIG. 23 is a view showing the appearance of a computer system for realizing the semiconductor manufacturing apparatus according to the embodiment of the present invention; and

FIG. 24 is a block diagram of the computer system used for realizing the semiconductor manufacturing apparatus according to the embodiment of the present invention.

### DETAILED DESCRIPTION OF THE INVENTION

The attached drawings for illustrating exemplary embodiments of the present invention are referred to in order to gain a sufficient understanding of the present invention, the merits thereof, and the objectives accomplished by the implementation of the present invention. Hereinafter, the present invention will be described in detail by explaining exemplary embodiments of the invention with reference to the attached drawings. Like reference numerals in the drawings denote like elements.

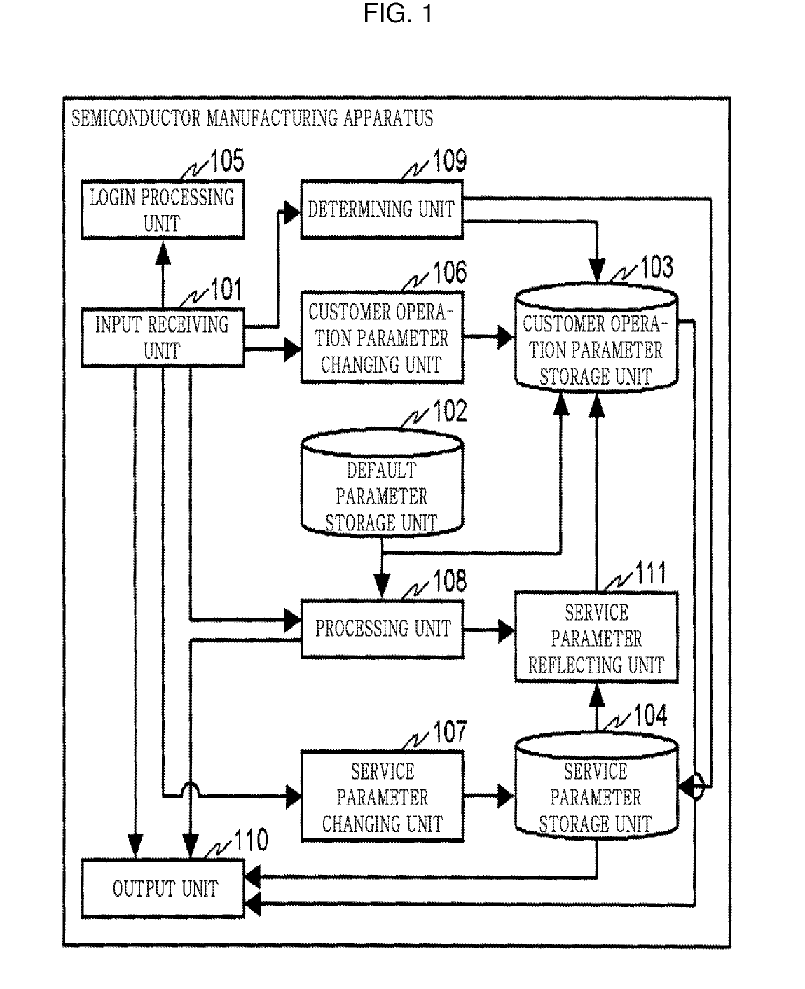

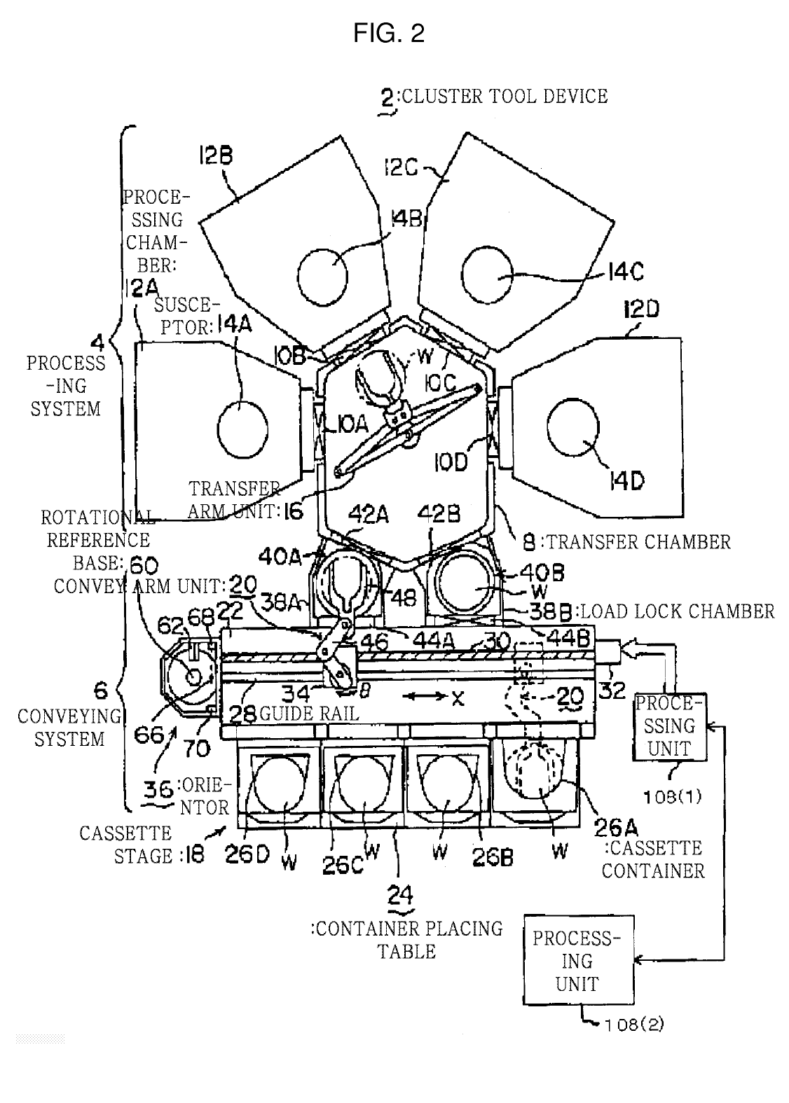

FIG. 1 is a block diagram of a semiconductor manufacturing apparatus according to an embodiment of the present invention. The semiconductor manufacturing apparatus includes an input receiving unit 101, a default parameter storage unit 102, a customer operation parameter storage unit 103, a service parameter storage unit 104, a login processing unit 105, a customer operation parameter changing unit 106, a service parameter changing unit 107, a processing unit 108, a determining unit 109, an output unit 110, and a service parameter reflecting unit 111. The semiconductor manufacturing apparatus of FIG. 1 does not include some machine elements included in the conventional semiconductor manufacturing apparatus, such as a processing system or a conveying system of FIG. 2.

The input receiving unit 101 receives various inputs from various users of the semiconductor manufacturing apparatus. Various users include, for example, an operator (customer) of the semiconductor manufacturing apparatus, a process engineer, a service engineer, etc., and types of users are not limited in the present invention. Various inputs received by the input receiving unit 101 include, for example, an input regarding login in a first mode, an input regarding login in a second mode, an instruction to change apparatus operation parameters, an input regarding the change in the apparatus operation parameters, an instruction to output change service parameters, an instruction regarding a complete change, an instruction regarding an individual change, an instruction to cancel the change, an operation instruction, an instruction to logout, a confirmation instruction, and the like. In this regard, the apparatus operation parameters are a set of one or more parameters used to operate the semiconductor manufacturing apparatus. The instruction to change the apparatus operation parameters is an instruction indicating a change in the apparatus operation parameters. The instruction to output the change service parameters is an instruction to output service parameters that have been changed. The instruction regarding the complete change is an instruction to completely overwrite the service parameters (or the changed service parameters only) with the customer operation parameters. The instruction regarding the individual change is an instruction to overwrite each designated service parameter with the customer operation parameters. The instruction to cancel the change is an instruction to invalidate overwriting of the service parameters with the customer operation parameters. The operation instruction is an instruction to operate the semiconductor manufacturing apparatus by using the apparatus operation parameters and manufacture a semiconductor. The instruction to logout is an instruction for various users to logout from the semiconductor manufacturing apparatus. The confirmation instruction is an instruction to confirm a difference between the service parameters and the customer operation parameters. An input of the confirmation instruction provides a user with, for example, the difference between the service parameters and the customer operation parameters. Devices used to input the various inputs include an input interface (e.g., a keyboard, a mouse, or a menu screen, etc.) of the semiconductor manufacturing apparatus, number keys (or a number key pad), a keyboard, a mouse, or a menu screen, etc. of an apparatus connected to the semiconductor manufacturing apparatus. The input receiving unit 101 may be realized as a device driver of an input device such as the number key pad or the keyboard or control software of the menu screen, etc.

The default parameter storage unit 102 stores default parameters, which are the apparatus operation parameters at default (e.g., at shipping). The default parameters may be initial values of the apparatus operation parameters. The default parameter storage unit 102 may be preferably a non-volatile recording medium but may also be realized as a volatile recording medium.

The customer operation parameter storage unit 103 stores the customer operation parameters. The customer operation parameters are the apparatus operation parameters that can be changed by an input of a user who logs in to the semiconductor manufacturing apparatus in the first mode. The input regarding login in the first mode is usually an input of a first user ID and a first password but may be an input (pressing a driving button) to start the semiconductor manufacturing apparatus. The input regarding login in the first mode may be the input of the first user ID only. In more detail, the input regarding login in the first mode may be an input to ensure that the semiconductor manufacturing apparatus identifies the first mode and the second mode. The first mode is, for example, a mode used by customers. The customer operation parameters are usually a group of parameters used by customers of the semiconductor manufacturing apparatus to manufacture the semiconductor but are not necessarily limited thereto. The customer operation parameters may be identified from the service parameters used by users who log in to the semiconductor manufacturing apparatus in the second mode. The customer operation parameter storage unit 103 may be preferably a non-volatile recording medium but may also be realized as a volatile recording medium.

The service parameter storage unit 104 stores the service parameters. The service parameters are the apparatus operation parameters that can be changed by an input of a user who logs in to the semiconductor manufacturing apparatus in the second mode. The second mode is, for example, a mode used by the service engineer. In this case, the second mode may be different from the first mode. Also, the second mode and the first mode are different when different users (or different types of users) log in to the semiconductor manufacturing apparatus. In the same manner as the customer operation parameters, the service parameters do not need service engineers as users and may be identified from the customer operation parameters used by users who log in to the semiconductor manufacturing apparatus in the first mode. The service parameter storage unit 104 may be preferably a non-volatile recording medium but may also be realized as a volatile recording medium.

The login processing unit 105 processes login in the first mode when the input receiving unit 101 receives the input regarding login in the first mode, and processes login in the second mode when the input receiving unit 101 receives the input regarding login in the second mode. The processing of login includes comparing of, for example, an input user ID and password with a pair of a managed user ID and password and outputting a comparison result. In more detail, if the semiconductor manufacturing apparatus manages a pair of the input user ID and password, the login processing unit 105 permits login and displays a screen after login, and if the semiconductor manufacturing apparatus does not manage the pair of the input user ID and password, the login processing unit 105 does not permit login and displays an error screen. In this case, the login processing unit 105 stores one or more pairs of previously registered user IDs and passwords. The login processing unit 105 may, for example, compare the input user ID with the managed user ID, and if the input user ID is managed, permit login, and display the screen after login, and if the input user ID is not managed, the login processing unit 105 may not permit login, and display the error screen. Also, the processing of login may, for example, include driving the semiconductor manufacturing apparatus. In this case, the login processing unit 105 drives the semiconductor manufacturing apparatus, for example, if a user logs in to the semiconductor manufacturing apparatus in the first mode. Also, if the user logs in to the semiconductor manufacturing apparatus in the second mode, the login processing unit 105 compares the input user ID and password with a pair of the managed user ID and password, and if the input user ID and password are managed, permits login, and displays the screen after login, and if the input user ID and password are not managed, the login processing unit 105 does not permit login, and displays the error screen. The login processing unit 105 may be realized as a microprocessor unit (MPU) or memory. The sequence of operations processed by the login processing unit 105 may be usually realized by using software that is recorded in a recording medium such as read only memory (ROM). However, the sequence of operations processed by the login processing unit 105 may also be realized by using hardware (a dedicated circuit).

The customer operation parameter changing unit 106 changes the customer operation parameters stored in the customer operation parameter storage unit 103 if the input receiving unit 101 receives an input regarding a change in the apparatus operation parameters from the user who logs in to the semiconductor manufacturing apparatus in the first mode. The customer operation parameter changing unit 106 renews one or more parameters changed by the user, from among one or more parameters included in the customer operation parameters, according to a user's instruction to change the one or more parameters. The customer operation parameter changing unit 106 may be usually realized as an MPU or memory. The sequence operations processed by the customer operation parameter changing unit 106 may be usually realized by using software that is recorded in a recording medium such as ROM. However, the sequence operations processed by the customer operation parameter changing unit 106 may also be realized by using hardware (a dedicated circuit).

The service parameter changing unit 107 changes the service parameters stored in the service parameter storage unit 104 if the input receiving unit 101 receives an input regarding a change in the apparatus operation parameters from the user who logs in to the semiconductor manufacturing apparatus in the second mode. The service parameter changing unit 107 renews one or more parameters changed by the user, from among one or more parameters included in the service parameters, according to a user's instruction to change the one or more parameters. The service parameter changing unit 107 may be usually realized as an MPU or memory. The sequence operations processed by the service parameter changing unit 107 may be usually realized by using software that is recorded in a recording medium such as ROM. However, the sequence operations processed by the service parameter changing unit 107 may also be realized by using hardware (a dedicated circuit).

The processing unit 108 reads at least the customer operation parameters or the service parameters and performs a semiconductor manufacturing process according to the read parameters (the apparatus operation parameters). If the processing unit 108 uses the customer operation parameters and the service parameters, the semiconductor manufacturing apparatus does not need the default parameter storage unit 102. Alternatively, the processing unit 108 reads at least the default parameters, the customer operation parameters, or the service parameters and performs the semiconductor manufacturing process according to the read parameters. In this case, the semiconductor manufacturing apparatus needs the default parameter storage unit 102. The processing unit 108 may determine various ways to perform the semiconductor manufacturing process according to how to use the customer operation parameters and the service parameters or the default parameters, the customer operation parameters, and the service parameters. For example, the processing unit 108 reads the service parameters from the service parameter storage unit 104, reads the customer operation parameters corresponding to the parameters that are not defined as the service parameters from the customer operation parameter storage unit 103, and performs the semiconductor manufacturing process according to the read parameters. As another example, if the user logs in to the semiconductor manufacturing apparatus in the first mode, the processing unit 108 reads the customer operation parameters from the customer operation parameter storage unit 103, and performs the semiconductor manufacturing process according to the one or more read parameters. As another example, if the user logs in to the semiconductor manufacturing apparatus in the second mode, the processing unit 108 reads the service parameters from the service parameter storage unit 104, and performs the semiconductor manufacturing process according to the one or more read parameters. As another example, the processing unit 108 reads the service parameters from the service parameter storage unit 104, reads the customer operation parameters corresponding to the parameters that are not defined as the service parameters from the customer operation parameter storage unit 103, reads the default parameters corresponding to the parameters that are not defined as the service parameters or the customer operation parameters from the default parameter storage unit 102, and performs the semiconductor manufacturing process according to the read parameters. The semiconductor manufacturing process includes, for example, various processing operations, such as filming, spreading, etching, etc. with regard to a semiconductor wafer that is an object to be conveyed. The semiconductor manufacturing process may include, for example, placing the semiconductor wafer into or removing it from a processing system. The processing unit 108 may be usually realized as an MPU or memory. The sequence operations processed by the processing unit 108 may be usually realized by using software that is recorded in a recording medium such as ROM. However, the sequence operations processed by the processing unit 108 may also be realized by using hardware (a dedicated circuit).

The determining unit 109 reads the customer operation parameters from the customer operation parameter storage unit 103, the service parameters from the service parameter storage unit 104, compares the read customer operation parameters with the read service parameters, and determines whether the customer operation parameters and the service parameters are different from each other. The determining unit 109 determines whether the customer operation parameters and the service parameters are different from each other by comparing one or more corresponding parameters between the customer operation parameters and the service parameters. The determining unit 109 determines that the customer operation parameters and the service parameters are different from each other if the one or more corresponding parameters between the customer operation parameters and the service parameters are partially different from each other. The determining unit 109, for example, writes ‘1 ’ to the memory if the determining unit 109 determines that the customer operation parameters and the service parameters are different from each other, and writes ‘0 ’ to the memory if the determining unit 109 determines that the customer operation parameters and the service parameters are identical to each other. The determining unit 109 may be usually realized as an MPU or memory. The sequence operations processed by the determining unit 109 may be usually realized by using software that is recorded in a recording medium such as ROM. However, the sequence operations processed by the determining unit 109 may also be realized by using hardware (a dedicated circuit).

The output unit 110 outputs comparing information indicating that the customer operation parameters and the service parameters are different from each other if the determining unit 109 determines that the customer operation parameters and the service parameters are different from each other. The comparison information may be information (in the form of a warning) indicating, for example, “the customer operation parameters and the service parameters are different from each other” or may be information about the customer operation parameters and the service parameters, which are different from each other. If the input receiving unit 101 receives an instruction to output the changed service parameters, the output unit 110 may not output the comparison information, but may read and output the service parameters changed by the service parameter changing unit 107 from the service parameter storage unit 104. In this case, the output unit 110 may output the comparison information indicating that “the customer operation parameters and the service parameters are different from each other” and the service parameters changed by the service parameter changing unit 107. The output unit 110 may output information other than the comparison information, according to the input received by the input receiving unit 101.

In this regard, the output includes displaying information on a display included in the semiconductor manufacturing apparatus, printing information through a printer connected to the semiconductor manufacturing apparatus, outputting information by sound, transmitting information to an external device connected to the semiconductor manufacturing apparatus, storing information in a recording medium, and the like. The output unit 110 may or may not include an output device such as a display or a speaker. The output unit 110 may be realized as only driver software of the output device or both an output device and the driver software of the output device.

The service parameter reflecting unit 111 completely overwrites the service parameters with the customer operation parameters when the input receiving unit 101 receives the instruction regarding a complete change. The service parameter reflecting unit 111 overwrites parameters including the service parameters corresponding to a corresponding individual change instruction with parameters corresponding to the customer operation parameters when the input receiving unit 101 receives the instruction regarding an individual change. The service parameter reflecting unit 111 may be usually realized as an MPU or memory. The sequence operations processed by the service parameter reflecting unit 111 may be usually realized by using software that is recorded in a recording medium such as ROM. However, the sequence operations processed by the service parameter reflecting unit 111 may also be realized by using hardware (a dedicated circuit).

Structural elements of the semiconductor manufacturing apparatus of the present embodiment will now be described with reference to FIG. 2. A multi-chambered semiconductor manufacturing apparatus, in particular, a cluster tool device 2, will now be described with reference to FIG. 2. Referring to FIG. 2, the cluster tool device 2 includes a processing system 4 that performs various processing operations such as filming, spreading, etching, etc. with respect to the semiconductor wafer W that is the object to be conveyed, and a conveying system 6 that places the semiconductor wafer W in and removes it from the processing system 4. The processing unit 108 of the semiconductor manufacturing apparatus is divided into two processing units 108(1) and 108(2), which will be described later.

The processing system 4 includes a transfer chamber 8 that can be evacuated and four processing chambers 12A through 12D that are connected through four gate valves 10A through 10D. Each of the processing chambers 12A through 12D performs a homogenous or heterogeneous thermal treatment with regard to the semiconductor wafer W. Four susceptors 14A through 14D, where the semiconductor wafer W can be placed, are formed in the processing chambers 12A through 12D, respectively. A transfer arm unit 16 that is flexible and can revolve is formed in the transfer chamber 8 to move the semiconductor wafer W back and forth between the processing chambers 12A through 12D and between load lock chambers that will be described later.

The conveying system 6 includes a cassette stage 18 used to place a plurality of cassette containers and a convey stage 22 used to move a convey arm unit 20 that conveys the semiconductor wafer W so as to move the semiconductor wafer W back and forth. A container placing table 24 is formed in the cassette stage 18, for placing a plurality of cassette containers, i.e. four cassette containers 26A through 26D. Each of the cassette containers 26A through 26D is designed to contain the semiconductor wafer W at the maximum, e.g., 25 sheets, having the same pitch.

A guide rail 28 is formed to extend the center of the convey stage 22 in a lengthwise direction and slidably supports the convey arm unit 20. A ball screw 30 that is a moving tool is formed in parallel to the guide rail 28. A base 34 of the convey arm unit 20 is inserted into the ball screw 30. Thus, the convey arm unit 20 moves along the guide rail 28 by rotating a driving motor 32 formed in an end portion of the ball screw 30.

An orientor (orientation determinator) 36 that is used to determine orientation of the semiconductor wafer W is formed in the other end of the convey stage 22. Two load lock chambers 38A and 38B that can be evacuated are formed in the convey stage 22 to connect the convey stage 22 and the transfer chamber 8. Two placing tables 40A and 40B for the object to be conveyed are formed in the load lock chambers 38A and 38B, respectively, to place the semiconductor wafer W thereon. Four gate valves 42A, 42B, 44A, and 44B are formed before and after the load lock chambers 38A and 38B, respectively, to connect the load lock chambers 38A and 38B to the transfer chamber 8 or the convey stage 22.

The convey arm unit 20 includes a flexible multi-jointed convey arm body 46 and a fork 48 attached to an edge of the convey arm body 46. The semiconductor wafer W is directly supported by the fork 48. The orientor 48 includes a rotational reference base 60, on which the semiconductor wafer W is placed, and the rotational reference base 60 is rotated by the driving motor 32. An optical sensor 62 is formed on the circumference of the rotational reference base 60 to detect the circumferential portion of the semiconductor wafer W. A level detector, which includes a laser unit 68 that outputs a horizontal level detection laser beam 66 and a beam receiving unit 70 that receives the horizontal level detection laser beam 66, is formed in an inlet side of the orientor 36.

The cluster tool device 2 includes the processing unit 108(1) that controls the whole operation of the cluster tool device 2, and controls conveyance of the semiconductor wafer W by collecting position information of each axis or information obtained by the level detector and the like.

The processing unit 108(1) includes a memory (not shown) that stores an apparatus control program and is configured in, for example, a flash memory, Erasable Programmable ROM (EPROM), electrically EPROM (EEROM), etc. The apparatus operation parameters (the one or more parameters read from the default parameter storage unit 102, the customer operation parameter storage unit 103, and a service parameter storage unit 104) are developed in the memory. The processing unit 108(1) executes the apparatus control program stored in the memory and controls the semiconductor manufacturing apparatus based on execution values of the apparatus operation parameters developed in the memory. The processing unit 108(1) includes, for example, an auxiliary storage unit (not shown) configured in a memory card and a card reader to store information that is to be used later. For example, a user may use an input unit (not shown) to instruct the processing unit 108(1) or use the output unit 110 to see a message of the processing unit 108(1). The processing unit 108(1) may include, for example, an interface unit (not shown) connected to a communication network (or a bus) to exchange information between the processing unit 108(2) that controls a device or another machine controller (not shown) and the processing unit 108(1).

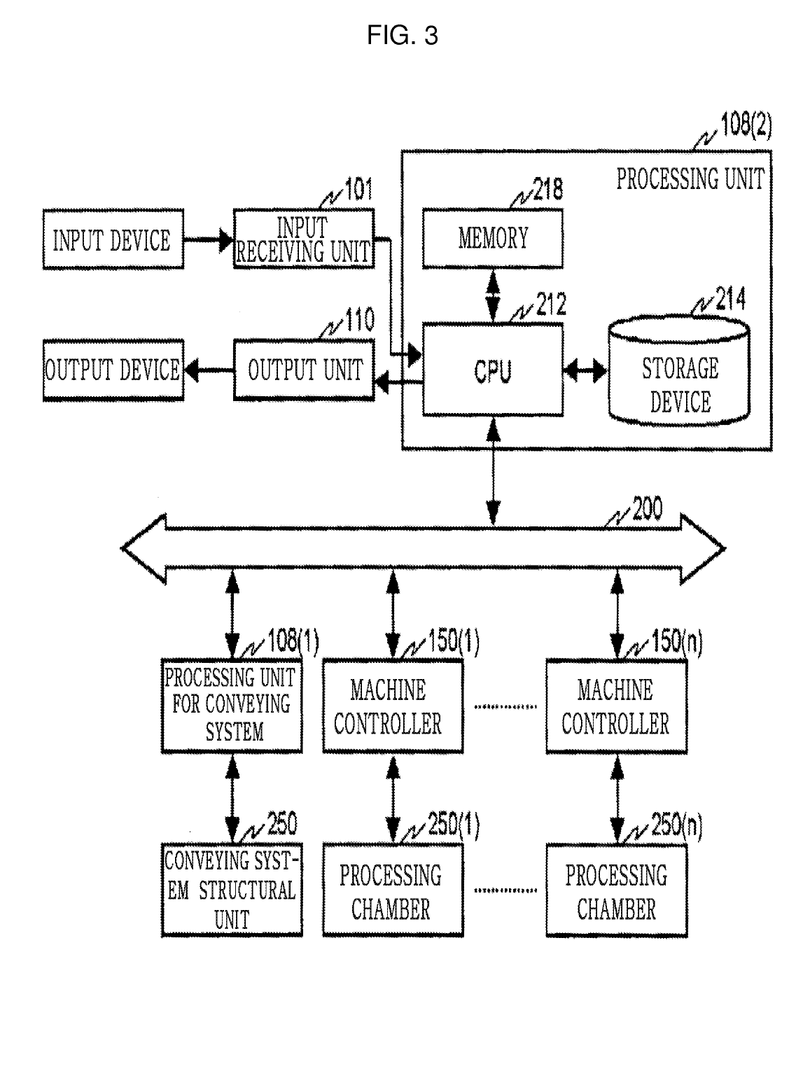

FIG. 3 is a block diagram of the processing unit 108(2) of the semiconductor manufacturing apparatus according to the embodiment of the present invention. Referring to FIG. 3, the processing unit 108(2) controls a device and includes a device controller 210, the processing unit 108(1) for the conveying system 6, a plurality of machine controllers 150₁ through 150ₙ, and a network 200 or a bus 200 that connects the processing unit 108(2), the processing unit 108(1) for the conveying system 6, and the machine controllers 150₁ through 150ₙ.

The processing unit 108(2) is used to manage all the information of the semiconductor manufacturing apparatus, and may be, for example, connected to a host computer (not shown) of a factory in which the semiconductor manufacturing apparatus is installed. The processing unit 108(2) includes a storage device 214, such as a hard disk unit, a flexible disk unit, or an integrated circuit (IC) memory unit, etc., and temporarily stores various types of information necessary for the operation of the semiconductor manufacturing apparatus. The storage device 214 temporarily stores, for example, a program for the operation of the processing unit 108(2), an apparatus operation program executed by the processing unit 108(1) to operate the conveying system 6, the apparatus operation parameters corresponding to the apparatus operation program, or apparatus operation programs executed by the machine controllers 150₁ through 150ₙ for controlling processes of various processing chambers 250₁ through 250ₙ and files regarding the apparatus operation parameters corresponding to the apparatus operation programs, a user's intrinsic recipe, log data of the semiconductor manufacturing apparatus, and the like. The processing unit 108(2) reads the apparatus operation parameters from the default parameter storage unit 102, the customer operation parameter storage unit 103, and the service parameter storage unit 104, which are not shown in FIG. 3, and temporarily stores the read apparatus operation parameters in the storage device 214. The storage unit 214 may include the default parameter storage unit 102, the customer operation parameter storage unit 103, and the service parameter storage unit 104. The processing unit 108(2) includes a central processing unit (CPU) 212 for executing the programs, downloads, for example, the various types of information stored in the storage device 214 in the processing unit 108(1) and the machine controllers 150₁ through 150ₙ through the network 200 or obtains the various types of information from the processing unit 108(1) and the machine controllers 150₁ through 150ₙ, and stores the downloaded or obtained information in the memory 218 or the storage device 214. The user may establish and edit the various programs stored in the storage device 214 and the apparatus operation parameters of the default parameter storage unit 102, the customer operation parameter storage unit 103, and the service parameter storage unit 104 by using the input unit (not shown).

The semiconductor manufacturing apparatus mentioned above is exemplary and may be an apparatus for performing an operation during a semiconductor manufacturing process. An input device may be, for example, a keyboard. An output device may be, for example a display.

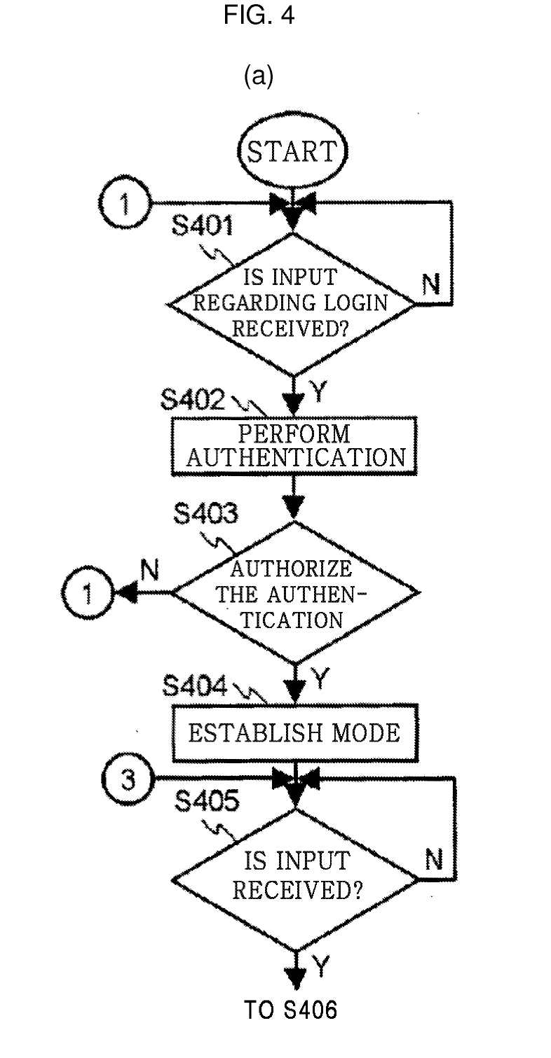

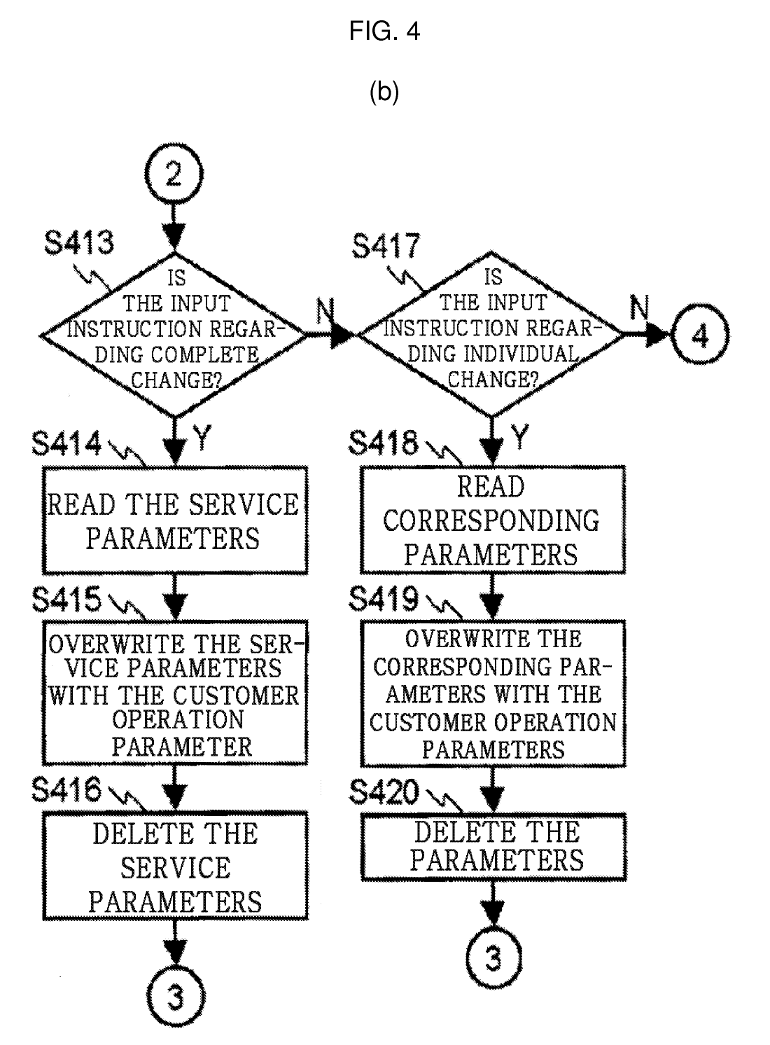

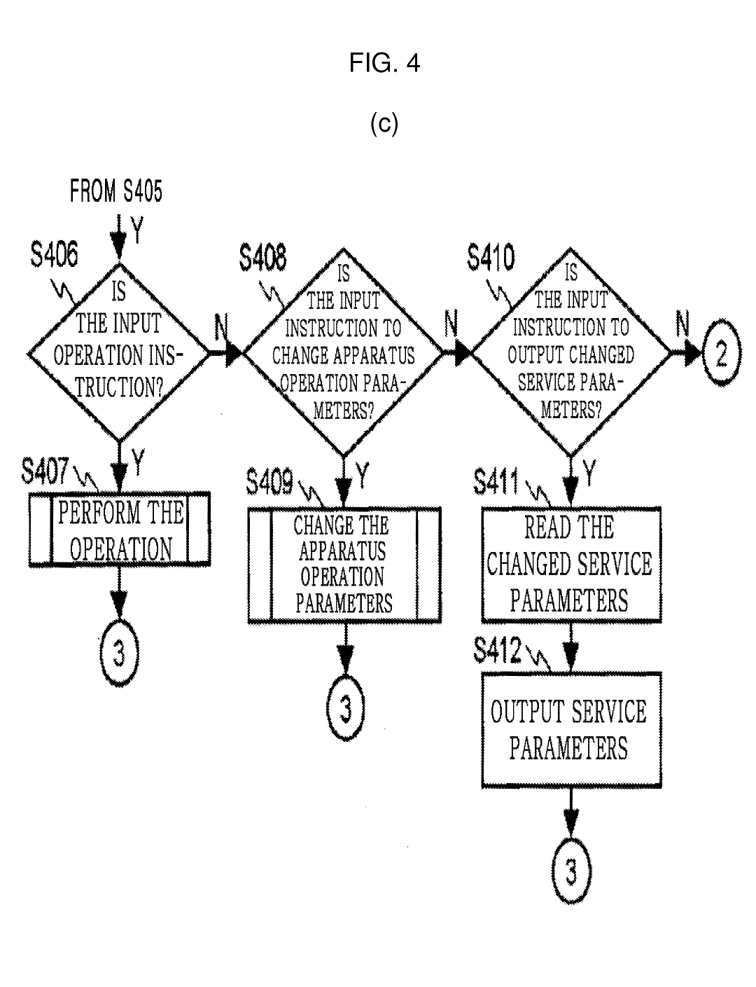

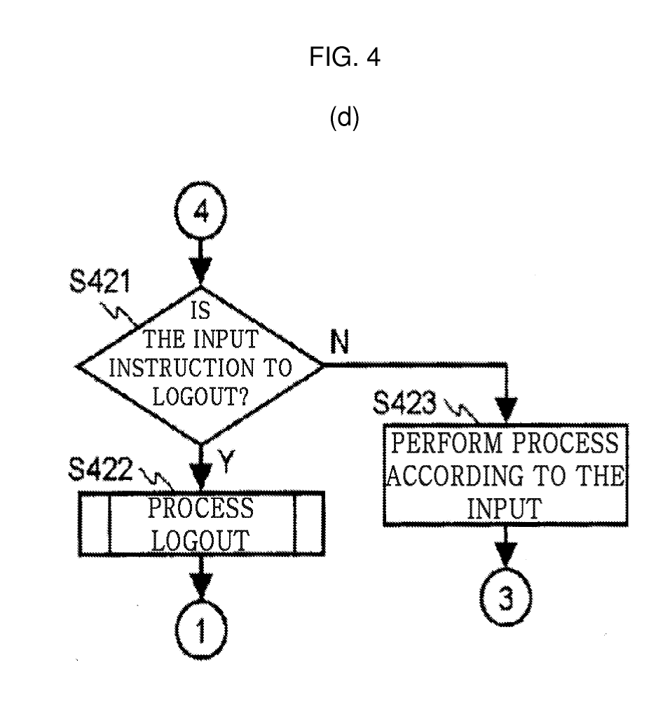

The operation of the semiconductor manufacturing apparatus will now be described with reference to flowcharts illustrated in FIGS. 4 through 7. In particular, a process of managing the apparatus operation parameters to adjust the operation conditions of the semiconductor manufacturing apparatus will now be described with reference to a flowchart illustrated in FIG. 4.

In step 401, the input receiving unit 101 determines whether an input regarding login is received. If the input receiving unit 101 determines that the input regarding login is received, step 402 is performed. If not, step 401 is performed again. The input regarding login is, for example, an input of a user ID and password.

In step 402, the login processing unit 105 performs authentication processing according to the input regarding login received in step 401. The authentication processing includes, for example, determining whether a pair of the received user ID and password are managed. The authentication processing is well known and thus a detailed description thereof will not be given here.

In step 403, the login processing unit 105 determines whether authentication performed in step 402 is authorized. If the login processing unit 105 determines that authentication is authorized, step 404 is performed. If not, step 401 is performed again.

In step 404, the login processing unit 105 determines a user mode according to the received input regarding login and temporarily assigns the determined user mode to a memory. The login processing unit 105 stores, for example, a pair of a user ID and user mode in a recording medium, reads a user mode that is paired with the received user ID in step 401, and temporarily assigns the read user mode to the memory.

In step 405, the input receiving unit 101 determines whether an input is received. If the input receiving unit 101 determines that the input is received, step 406 is performed. If not, step 405 is performed again.

In step 406, the processing unit 108 determines whether the input received in step 405 is an operation instruction. If the processing unit 108 determines that the input is the operation instruction, step 407 is performed. If not, step 408 is performed.

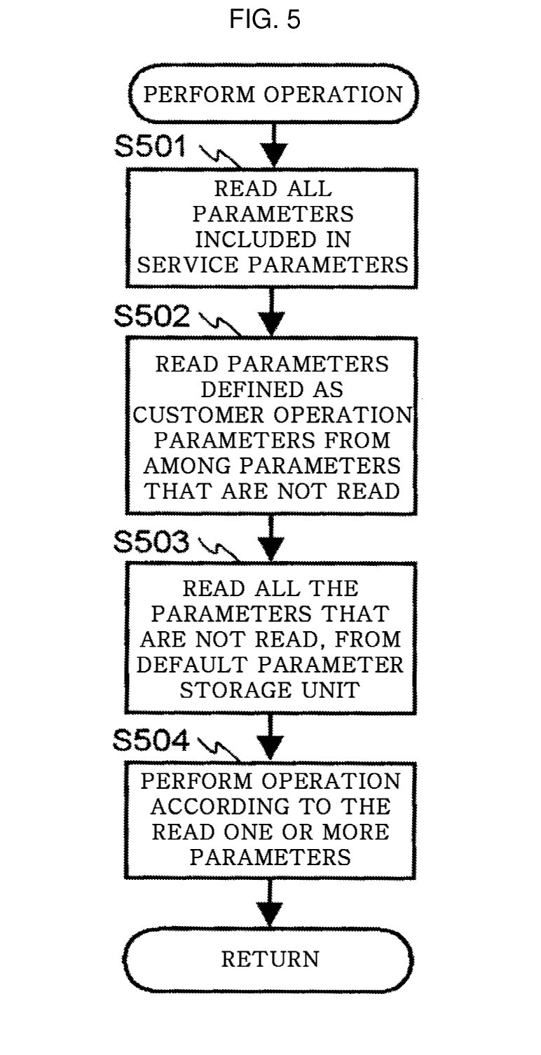

In step 407, the processing unit 108 performs an operation according to the operation instruction determined in step 406. Step 407 will be described in more detail with reference to a flowchart illustrated in FIG. 5. Then, step 405 is performed again.

In step 408, the processing unit 108 determines whether the input received in step 405 is an instruction to change the apparatus operation parameters. If the processing unit 108 determines that the input is the instruction to change the apparatus operation parameters, step 409 is performed. If not, step 410 is performed.

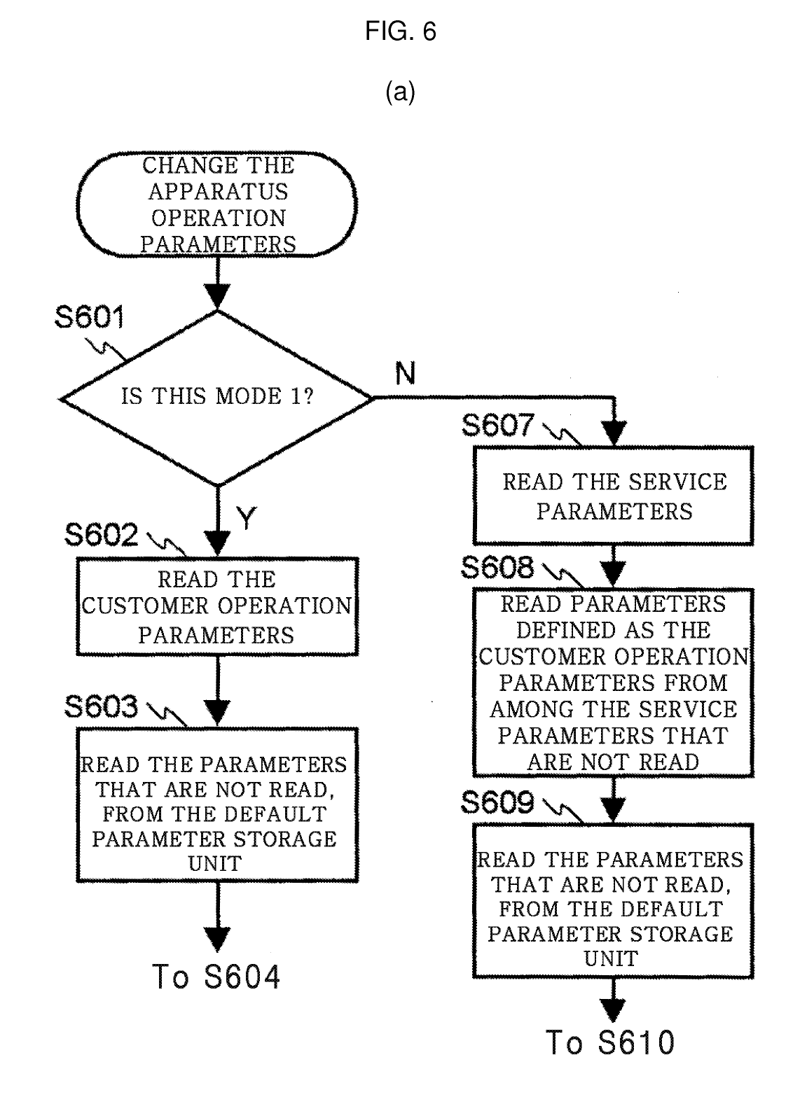

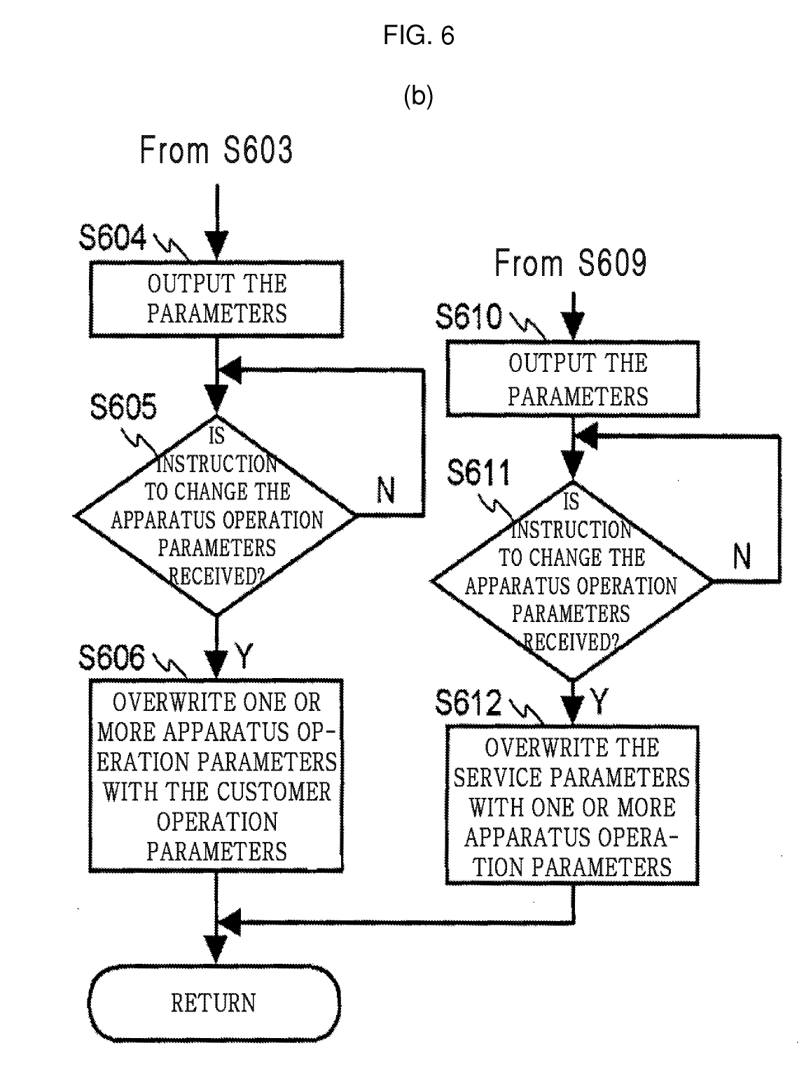

In step 409, the processing unit 108 changes the apparatus operation parameters. Step 409 will be described in more detail with reference to a flowchart illustrated in FIG. 6. Then, step 405 is performed again.

In step 410, the processing unit 108 determines whether the input received in step 405 is an instruction to output changed service parameters. If the processing unit 108 determines that the input is the instruction to output the changed service parameters, step 411 is performed. If not, step 413 is performed.

In step 411, the output unit 110 reads the changed service parameters from the service parameter storage unit 104. The service parameter storage unit 104 includes, for example, one or more pairs of parameters and change flags. A change flag indicates a change in the service parameters. For example, if the service parameters are changed, the change flags are ‘1’, and if not, the change flags are ‘0’. In this case, the output unit 110 reads the parameters that are stored in the service parameter storage unit 104 and correspond to the change flag indicating ‘change (1)’. A set of one or more parameters comprises the service parameters. The changed service parameters may be all the parameters stored in the service parameter storage unit 104. In more detail, when the service parameters are determined, the service parameters may be overwritten with the customer operation parameters and all the parameters stored in the service parameter storage unit 104 may be deleted. In this case, the parameters stored in the service parameter storage unit 104 may be changed.

In step 412, the output unit 110 outputs the service parameters (one or more changed parameters) read in step 411. Then, step 405 is performed again.

In step 413, the processing unit 108 determines whether the input received in step 405 is an instruction regarding a complete change. If the processing unit 108 determines that the input is the instruction regarding the complete change, step 414 is performed. If not, step 417 is performed.

In step 414, the service parameter reflecting unit 111 reads the service parameters stored in the service parameter storage unit 104 or in the memory. The changed parameters may be preferable to the read service parameters. The changed parameters are, for example, separated from the unchanged parameters by establishing the change flags.

In step 415, the service parameter reflecting unit 111 overwrites each parameter included in the service parameters read in step 414 with each corresponding parameter stored in the customer operation parameter storage unit 103. The parameters included in the service parameters and included in the customer operation parameters may, for example, correspond to parameter IDs or parameter names. The parameters included in the service parameters and included in the customer operation parameters may, for example, correspond to other elements such as links.

In step 416, the service parameter reflecting unit 111 deletes all the parameters included in the service parameters stored in the service parameter storage unit 104. Step 416 is not necessarily required. Then, step 405 is performed again.

In step 417, the processing unit 108 determines whether the input received in step 405 is an instruction regarding an individual change. If the processing unit 108 determines that the input is the instruction regarding the individual change, step 418 is performed. If not, step 421 is performed.

In step 418, the service parameter reflecting unit 111 reads the parameters according to the instruction regarding the individual change from the service parameter storage unit 104 or the memory.

In step 419, the service parameter reflecting unit 111 overwrites corresponding parameters stored in the customer operation parameter storage unit 103 with the parameters read in step 418.

In step 420, the service parameter reflecting unit 111 deletes the parameters included in the service parameters, which were overwritten in step 419. Step 420 is not necessarily required. Then, step 405 is performed again.

In step 421, the processing unit 108 determines whether the input received in step 405 is an instruction to logout. If the processing unit 108 determines that the input is the instruction to logout, step 422 is performed. If not, step 423 is performed.

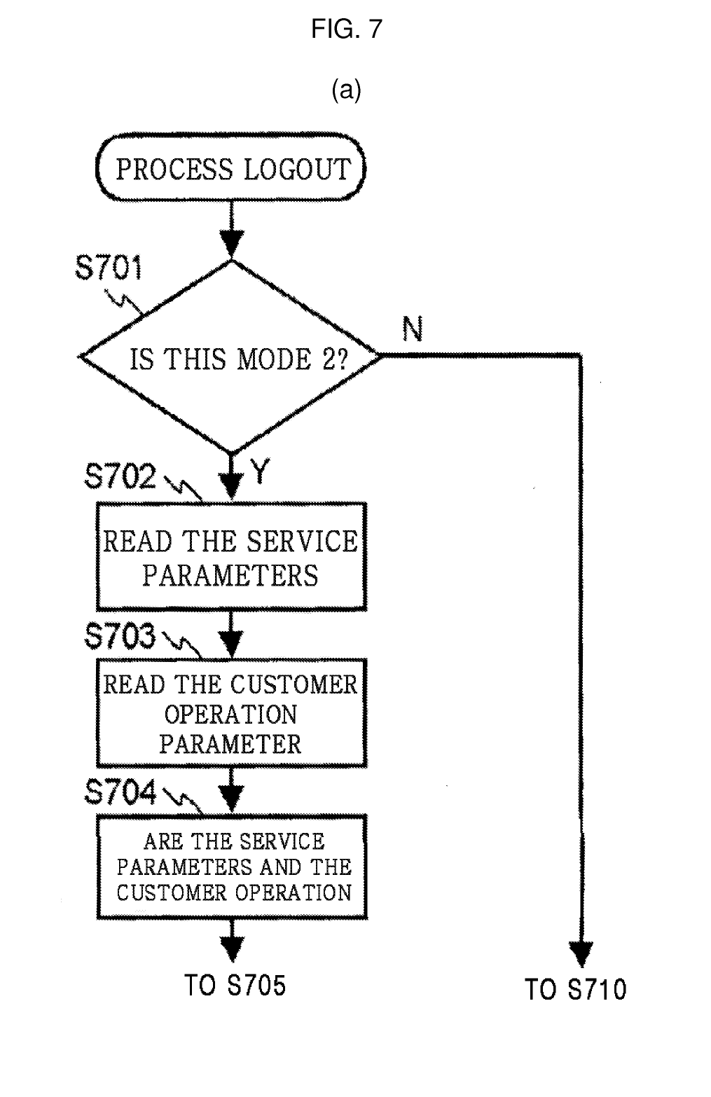

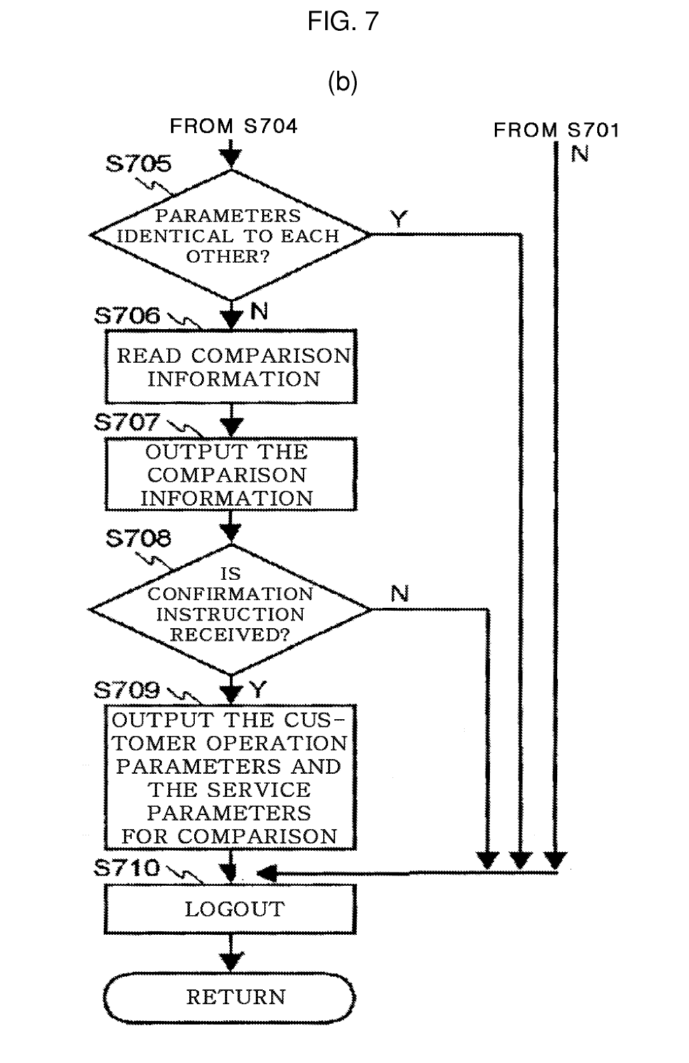

In step 422, the processing unit 108 performs a logout process. Then, step 401 is performed again. Step 422 will be described in more detail described with reference to a flowchart illustrated in FIG. 7. Then, step 401 is performed again.

In step 423, an element that is not shown or the processing unit 108 performs a processing operation according to the input received in step 401. Then, step 405 is performed again. The processing operation may include various processing operations performed by the semiconductor manufacturing apparatus.

The semiconductor manufacturing apparatus ends steps 410 through 423 of the flowchart illustrated in FIG. 4 if power is turned off or there is an abrupt end of a process.

The performing of the operation according to the operation instruction in step 407 will now be described with reference to FIG. 5.

In step 501, the processing unit 108 reads all the parameters included in the service parameters stored in the service parameter storage unit 104. All the parameters comprise service parameters which each have a value.

In step 502, the processing unit 108 reads parameters defined as the customer operation parameters, which are from among parameters that are not read in step 501, from the customer operation parameter storage unit 103. The processing unit 1008 does not read the customer operation parameters which have no value.

In step 503, the processing unit 108 reads all the parameters that are not read in steps 501 and 502 from the default parameter storage unit 102. If the processing unit 108 reads all the parameters in steps 501 and 502, step 503 is not performed.

In step 504, the processing unit 108 performs an operation according to the one or more parameters read in steps 501 through 503. The process then returns to an earlier step. A semiconductor may be manufactured by performing steps 510 through 504. Step 504 is well known and thus a detailed description thereof will not be given here.

Steps 510 through 504 illustrated in FIG. 5 may be performed by the semiconductor manufacturing apparatus when a service engineer logs in to the semiconductor manufacturing apparatus in a “mode=2” and inputs an operation instruction. In this case, when a customer logs in to the semiconductor manufacturing apparatus in a “mode=1” and inputs an operation instruction, in steps 510 through 504, the processing unit 108 of the semiconductor manufacturing apparatus reads all the parameters defined as the customer operation parameters from the customer operation parameter storage unit 103, reads all parameters that are not read from the customer operation parameter storage unit 103 from the default parameter storage unit 102, and performs an operation according to the read parameters.

Steps 510 through 504 may be performed by all users who log in to the semiconductor manufacturing apparatus in the mode=1 and mode=2. In this case, parameters changed by the service engineer are generally reflected as customer parameters. That is, a parameter management method and processing of operations may correspond to each other without any mismatch.

Next, the changing of the apparatus operation parameters in step 409 will be described with reference to FIG. 6.

In step 601, the output unit 110 determines whether a mode is 1. If the output unit 110 determines that the mode is 1, the output unit 110 proceeds with step 602. If not, the output unit 110 proceeds with step 607. In this regard, if the mode is not 1, the mode is 2.

In step 602, the output unit 110 reads the customer operation parameters from the customer operation parameter storage unit 103 and allocates the read customer operation parameters to the memory.

In step 603, the output unit 110 reads the parameters that are not read in step 602 from the default parameter storage unit 102 and allocates the read parameters to the memory.

In step 604, the output unit 110 outputs the customer operation parameters and the parameters read in steps 602 and 603, respectively.

In step 605, the input receiving unit 101 determines whether an instruction to change the apparatus operation parameters is received. If the input receiving unit 101 determines that the instruction to change the apparatus operation parameters is received, step 606 is performed. If not, step 605 is performed again.

In step 606, the customer operation parameter changing unit 106 overwrites the one or more apparatus operation parameters according to the instruction received in step 605 with the customer operation parameters. The process then returns to an earlier step.

In step 607, the output unit 110 reads the service parameters (a set of one or more parameters) from the service parameter storage unit 104 and allocates the read service parameters to the memory.

In step 608, the output unit 110 reads parameters defined as the customer operation parameters, which are from among the service parameters that are not read in step 607, from the customer operation parameter storage unit 103, and allocates the read parameters to the memory.

In step 609, the output unit 110 reads the service parameters and the customer operation parameters that are not read in steps 607 and 608 from the default parameter storage unit 102 and allocates the read service parameters and the customer operation parameters to the memory.

In step 610, the output unit 110 outputs the service parameters and the customer operation parameters read in steps 607 through 609.

In step 611, the input receiving unit 101 determines whether an instruction to change the apparatus operation parameters is received. If the input receiving unit 101 determines that the instruction to change the apparatus operation parameters is received, step 612 is performed. If not, step 611 is performed again.

In step 612, the service parameter changing unit 107 overwrites the service parameters with the one or more apparatus operation parameters according to the instruction received in step 611. The process then returns to an earlier step.

In steps 601 through 612, if the service parameters are changed, the customer operation parameters may be changed to be the same as the changed service parameters. In this case, the original customer operation parameters may preferably be kept unchanged by removing them from a recording medium such as the memory or a hard disk drive. If the original customer operation parameters remain unchanged, the changed customer operation parameters may be easily restored to their original values. This operation is the same as an undo operation of an editor or a roll back operation in a database and thus a detailed description thereof will not be given here.

The logout process performed in step 401 will be described with reference to FIG. 7.

In step 701, the determining unit 109 determines whether a mode is 2. If the determining unit 109 determines that the mode is 2, the determining unit 109 proceeds with step 702. If not, step 710 is performed.

In step 702, the determining unit 109 reads the service parameters from the service parameter storage unit 104 and allocates the read service parameters to the memory.

In step 703, the determining unit 109 reads the customer operation parameters from the customer operation parameter storage unit 103 and allocates the read customer operation parameters to the memory.

In step 704, the determining unit 109 compares the service parameters read in step 702 with the customer operation parameters read in step 703 and determines whether the service parameters and the customer operation parameters are identical to each other. If the service parameters and the customer operation parameters are different from each other, a change in the service parameters is not reflected in the customer operation parameters. Thus, when the change in the service parameters is reflected in the customer operation parameters, if the service parameters are deleted, the determining unit 109 does not compare the service parameters with the customer operation parameters and determines whether the service parameters are null. In this case, if the determining unit 109 determines that the service parameters are not null, the service parameters and the customer operation parameters are different from each other.

In step 705, if the determining unit 109 determines that the service parameters and the customer operation parameters are identical to each other, step 710 is performed. If not, step 706 is performed.

In step 706, the output unit 110 reads comparison information indicating that the service parameters and the customer operation parameters are different from each other. The comparison information is previously stored in a recording medium of the output unit 110. The comparison information includes, for example, message information indicating the message “There are changed service parameters. Please confirm the changed service parameters on a comparison screen.” and comparison screen information.

In step 707, the output unit 110 outputs the comparison information read in step 706.

In step 708, the input receiving unit 101 determines whether a confirmation instruction is received. If the input receiving unit 101 determines that the confirmation instruction is received, step 709 is performed. If not, step 710 is performed.

In step 709, the output unit 110 outputs the customer operation parameters and the service parameters to be compared.

In step 710, an element that is not shown processes user logout. The processing of user logout includes, for example, erasing of a user ID of a user who logs out from a group of user IDs of registered users who are logged in to the semiconductor manufacturing apparatus. The process then returns to an earlier step.

In steps 701 through 710, when a user logs out, the customer operation parameters and the service parameters are compared, if the customer operation parameters and the service parameters are different from each other, a warning message is output. The warning message may be output when the service parameters are changed or remain unchanged, the customer operation parameters are changed or remain unchanged, or an operation or manipulation accompanied by the change in the service parameters and the customer operation parameters is performed.

The operation of the semiconductor manufacturing apparatus of the present embodiment will now be described in more detail. A concept of the semiconductor manufacturing apparatus of the present embodiment is shown in FIG. 2.

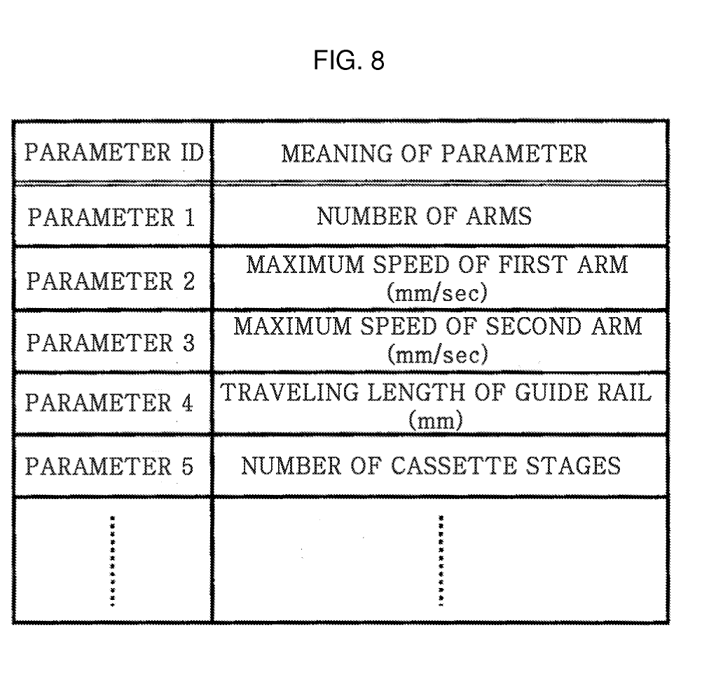

FIG. 8 is a table for managing the apparatus operation parameters used by the semiconductor manufacturing apparatus to execute a semiconductor manufacturing process. The table includes “parameter ID” indicating identification information of the apparatus operation parameters and “parameter meaning” attribute values indicating the meaning of the apparatus operation parameters. The apparatus operation parameters comprise several hundreds of thousands of parameters.

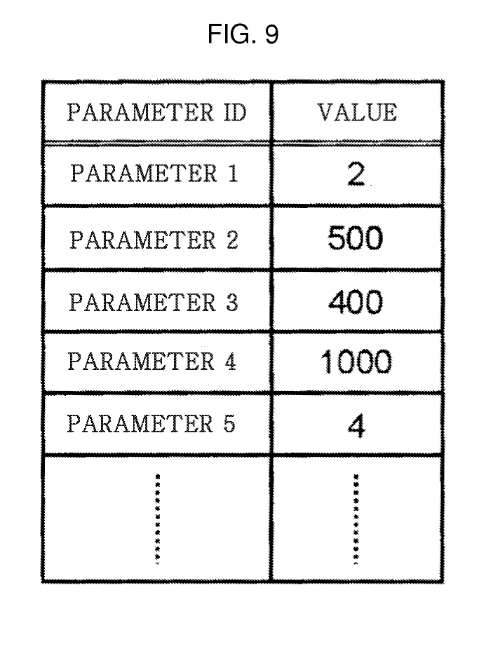

FIG. 9 is a table for managing the default parameters. The table includes examples of the default parameters stored in the default parameter storage unit 102 that are written in the semiconductor manufacturing apparatus at the shipping thereof. The table includes “parameter ID” and “value” attributes.

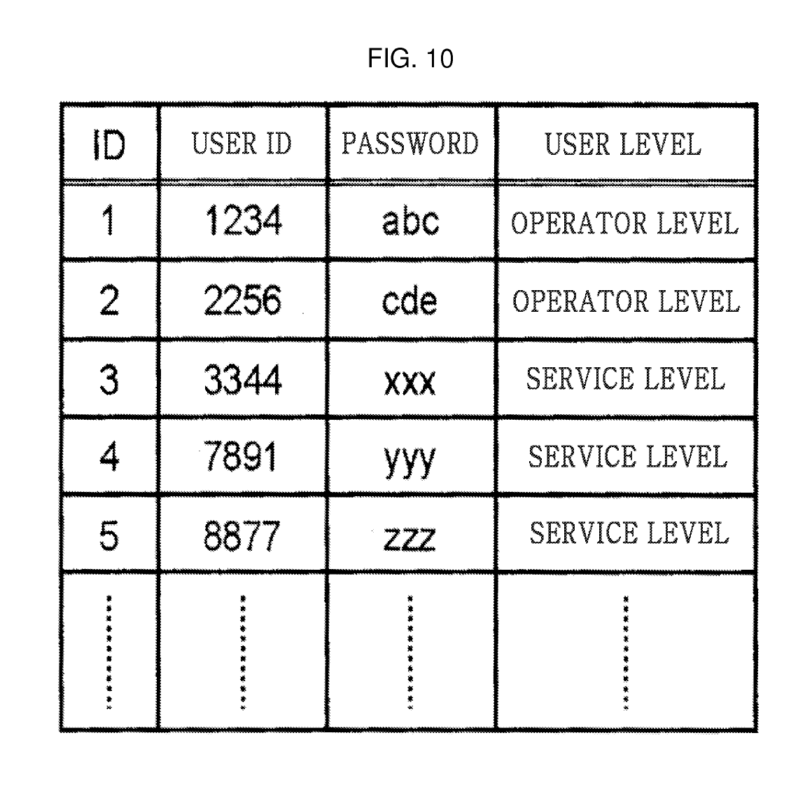

FIG. 10 is a table for managing users maintained by the login processing unit 105. The table includes “ID”, “user ID”, “password”, and “user level” attributes. The “ID” is information identifying a record and is used for record management. The “user ID” is information identifying users. The “password” is an attribute for storing a password. The “user level” is an attribute for storing a level of a user and corresponds to a mode. In this regard, the “user level” includes two types of operator level (a customer level) and a service level (a service engineer level). The “user level” includes another level (e.g., a process engineer level, etc.). An operator level user is a user who manufactures a semiconductor by using the semiconductor manufacturing apparatus and a customer of the semiconductor manufacturing apparatus. A service level user is a user who provides the semiconductor manufacturing apparatus and maintains or evaluates the semiconductor manufacturing apparatus. The service level user usually maintains or evaluates the semiconductor manufacturing apparatus in a field where the semiconductor manufacturing apparatus is operated.

Under these circumstances, a user A who is a customer of the semiconductor manufacturing apparatus inputs a user ID “2256” and a password “cde” by using an input device and presses a login button (not shown). The input receiving unit 101 receives the user ID “2256” and the password “cde”. The login processing unit 105 performs an authentication process by using the received user ID “2256” and the password “cde”. Since the user ID “2256” and the password “cde” are included in the table shown in FIG. 10, the login processing unit 105 authorizes authentication. The login processing unit 105 reads a user level “operator level” corresponding to the user ID “2256” from the table shown in FIG. 10. In this regard, the “operator level” is “1”. In more detail, the login processing unit 105 reads the user level “1” and establishes the user level “1” in the memory.

The user A inputs an instruction to change the apparatus operation parameters (e.g., presses a button for changing the apparatus operation parameters). The input receiving unit 101 receives the instruction to change the apparatus operation parameters.

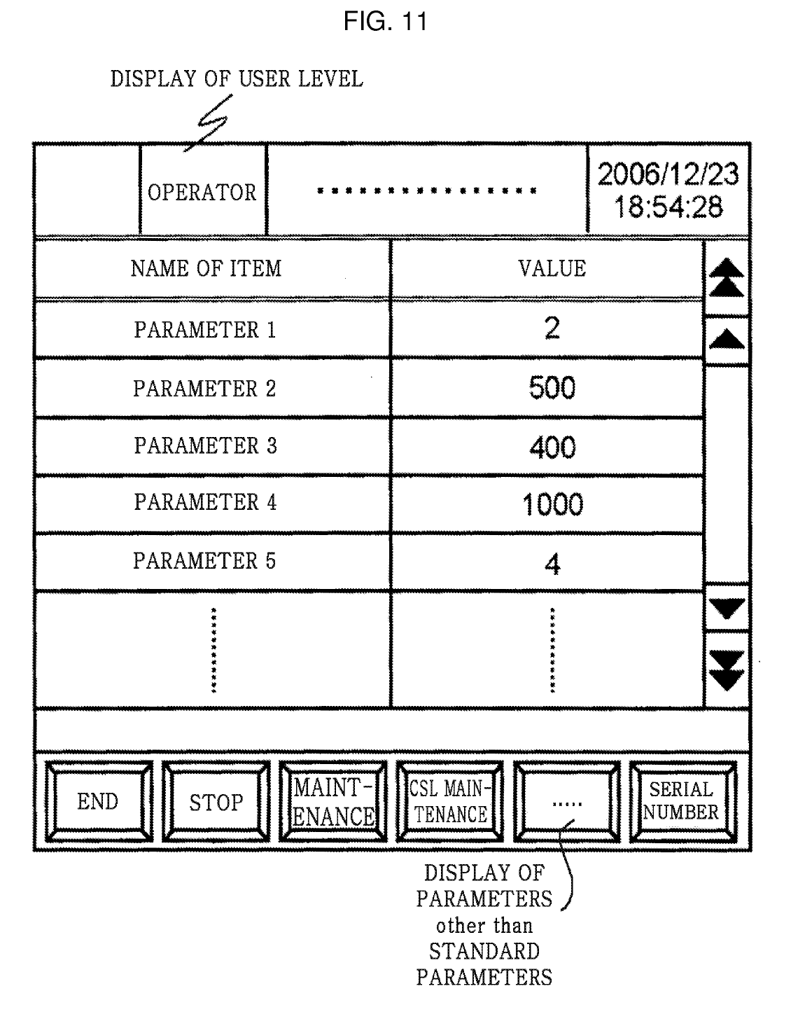

The output unit 110 determines whether a mode is “1”. Since the mode is “1”, the output unit 110 reads the customer operation parameters from the customer operation parameter storage unit 103 and allocates the read customer operation parameters to the memory. In this regard, the customer operation parameters are empty. That is, the output unit 110 failed to read the customer operation parameters from the customer operation parameter storage unit 103. The output unit 110 reads the default parameters shown in FIG. 9 from the default parameter storage unit 102 and allocates the read default parameters to the memory. The output unit 110 displays the read default parameters on a display shown in FIG. 11.

The user A corrects the maximum speed “500” of a first arm “parameter 2” to “400” on the display shown in FIG. 11 in order to adapt the semiconductor manufacturing apparatus to the environment of the user A. Likewise, the user A corrects the traveling length “1000” of a guide rail “parameter 4” to “800”. Then, the user A presses a button “maintenance” on the display shown in FIG. 11.

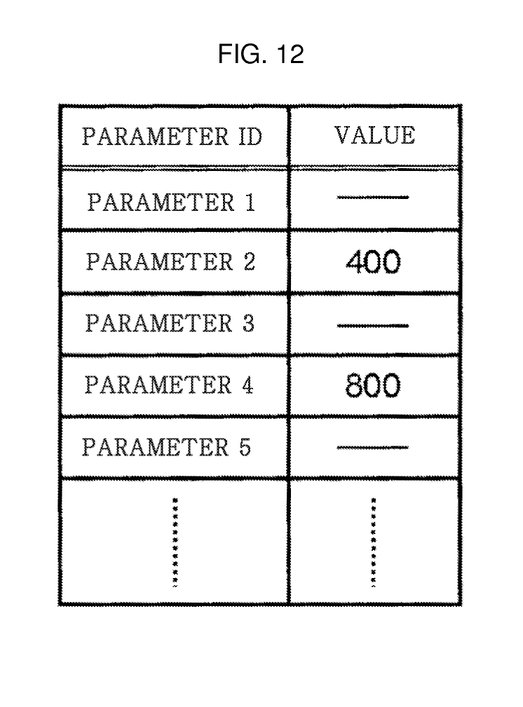

The input receiving unit 101 receives an instruction to change the apparatus operation parameters (user A inputs a value and presses the button “maintenance”). The customer operation parameter changing unit 106 obtains two parameters (parameter 2: 400 and parameter 4: 800) and writes the two obtained parameters on the customer operation parameters stored in the customer operation parameter storage unit 103 shown in FIG. 12. Referring to FIG. 12, parameters that are not written on the customer operation parameters stored in the customer operation parameter storage unit 103 are null.

The user A inputs an operation instruction (presses a button for executing the semiconductor manufacturing process of the semiconductor manufacturing apparatus). The input receiving unit 101 receives the operation instruction.

The processing unit 108 reads all the parameters defined as the customer operation parameters from the customer operation parameter storage unit 103. That is, the processing unit reads the two parameters (parameter 2: 400 and parameter 4: 800) and allocates the two read parameters to the memory.

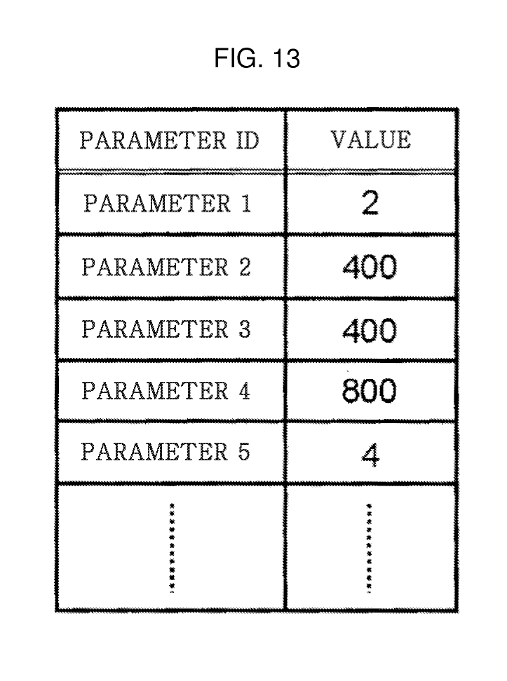

The processing unit 108 reads all parameters that are not read from the parameters defined as the customer operation parameters from the default parameters stored in the default parameter storage unit 102. Therefore, the apparatus operation parameters shown in FIG. 13 are obtained. The processing unit 108 executes the semiconductor manufacturing process according to the apparatus operation parameters shown in FIG. 13. As described above, the semiconductor manufacturing process is performed in the mode 1 that is a customer mode. The user A examines a manufacturing result to determine whether the established customer operation parameters are satisfactory or not. When the apparatus operation parameters are determined, execution of the semiconductor manufacturing process according to the determined apparatus operation parameters is well known and thus a detailed description thereof will not be given here.

A user B who is a service engineer tunes the apparatus operation parameters to maintain the semiconductor manufacturing apparatus.

The user B inputs a user ID “7891” and a password “yyy” by using an input device and presses a login button (not shown). The input receiving unit 101 receives the user ID “7891” and the password “yyy”. The login processing unit 105 performs an authentication process by using the received user ID “7891” and password “yyy”. Since the user ID “7891” and the password “yyy” are included in the table shown in FIG. 10, the login processing unit 105 reads the user level “service level” corresponding to the user ID “7891”. In this regard, the “service level” is “2”. That is, the login processing unit 105 reads the user level “2” and establishes the user level “2” in the memory.

The user B inputs an instruction to change the apparatus operation parameters (e.g., presses a button to change the apparatus operation parameters). The input receiving unit 101 receives the instruction to change the apparatus operation parameters. If a logged-in user is determined to be a service level user, the logged-in user may preferably move to an interface (screen) of a user different from that of an operator level user.

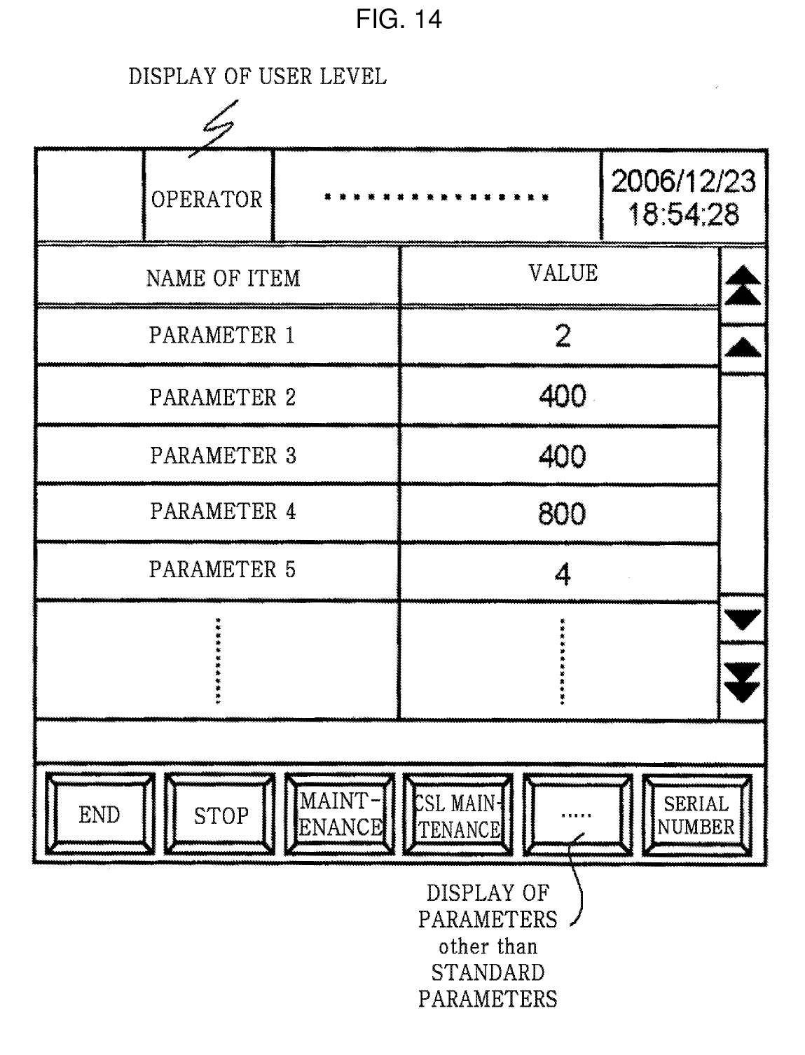

The output unit 110 determines whether a mode is “1”. Since the mode is not “1” (it is 2), the output unit 110 reads the service parameters (a set of one or more parameters) from the service parameter storage unit 104 and allocates the read service parameters to the memory. In this regard, the service parameters are empty. That is, the output unit 110 failed to read the service parameters from the service parameter storage unit 104. The output unit 110 reads the parameters (parameter 2: 400 and parameter 4: 800), which are defined as the customer operation parameters from among the parameters (all the parameters) that are not read from the service parameter storage unit 104, from the customer operation parameter storage unit 103, and allocates the read parameters to the memory. The output unit 110 reads all the parameters that are not read from the service parameter storage unit 104 from the default parameter storage unit 102 and allocates the read parameters to the memory. The output unit 110 displays the read parameters on a display shown in FIG. 14. Referring to FIG. 14, the customer operation parameters and the default parameters, which are visually separated from each other, are displayed on the display by changing the font, character color, or character size, etc. of the customer operation parameters and the default parameters. For example, regarding whether the parameters are read from the service parameter storage unit 104, the customer operation parameter storage unit 103, and the default parameter storage unit 102, the output unit 110 may preferably change the font, character color, or character size of the parameters according to values “0”, “1”, and “2” written to the memory by reading the parameters and making the parameters correspond to the values “0”, “1”, and “2”, respectively.

The user B corrects each parameter by trial and error in order to maintain the semiconductor manufacturing apparatus. In this regard, for example, the user B corrects the maximum speed “400” of a first arm “parameter 2” to “450” on the display shown in FIG. 14. Then, the user B presses a button “maintenance” on the display shown in FIG. 14.

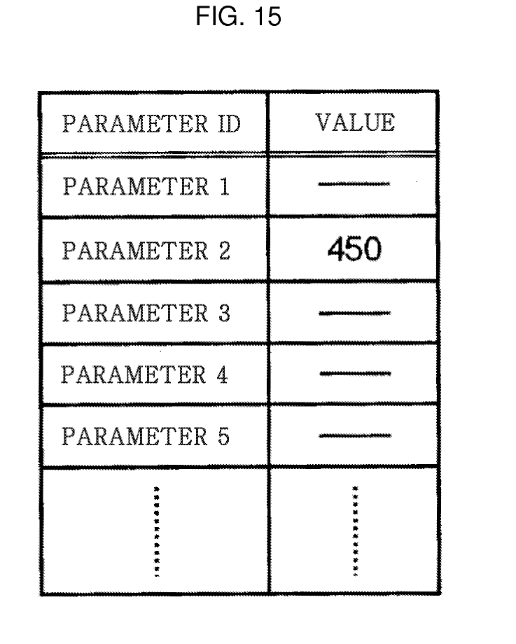

The input receiving unit 101 receives an instruction to change the apparatus operation parameters (user B inputs a value and presses the button “maintenance”). The service parameter changing unit 107 obtains a parameter (parameter 2: 450) according to the received instruction and writes the obtained parameter as the service parameters to be stored in the service parameter storage unit 104 shown in FIG. 15. Referring to FIG. 15, parameters that are not written as the service parameters in the service parameter storage unit 104 are null.

The user B performs the semiconductor manufacturing process in order to evaluate established service parameters. That is, the user B inputs an operation instruction (presses a button for executing the semiconductor manufacturing process of the semiconductor manufacturing apparatus). The input receiving unit 101 receives the operation instruction.

The processing unit 108 reads all the parameters (parameter 2: 450) included in the service parameters stored in the service parameter storage unit 104 and allocates the read parameter to the memory.

The processing unit 108 reads a parameter (parameter 4: 800) that is not read from the parameters defined as the customer operation parameters which are from among the parameters that are not read from the service parameter storage unit 104, from the customer operation parameter storage unit 103 and allocates the read parameter to the memory.

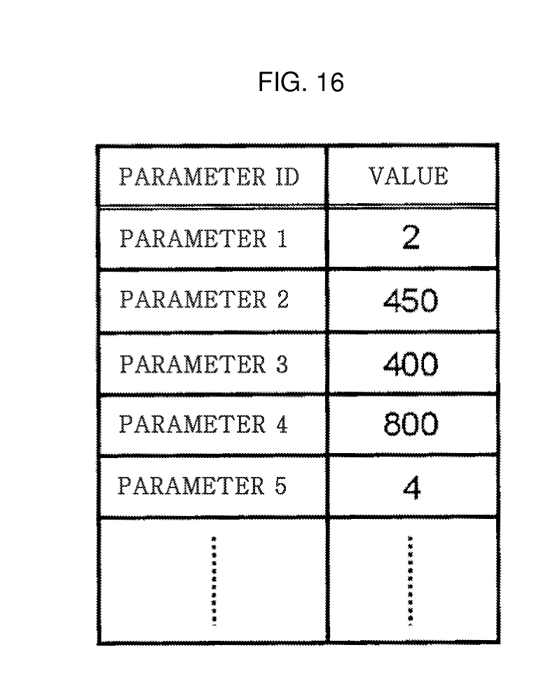

The processing unit 108 reads all parameters, which are not read from the service parameter storage unit 104 and the customer operation parameter storage unit 103, from the parameters stored in the default parameter storage unit 102. Therefore, the apparatus operation parameters shown in FIG. 16 are obtained. The processing unit 108 executes the semiconductor manufacturing process according to the apparatus operation parameters shown in FIG. 16. As described above, the semiconductor manufacturing process is performed in the mode 2 that is a service mode. The user B examines a manufacturing result to determine whether the established customer operation parameters are satisfactory or not. In this regard, the service parameters established by the user B are more preferable for completely manufacturing an excellent semiconductor.

The user B processes a logout input (e.g., presses a logout button). The input receiving unit 101 receives an instruction to logout. The processing unit 108 performs a logout processing operation as described below.

The determining unit 109 determines whether a mode is 2. In this regard, since the mode is 2 (login of a service engineer), the determining unit 109 reads the service parameters from the service parameter storage unit 104 and allocates the read service parameters to the memory. The determining unit 109 reads the customer operation parameter from the customer operation parameter storage unit 103 and allocates the read customer operation parameters to the memory. The determining unit 109 compares the read service parameters with the read customer operation parameters and determines whether the read service parameters and the read customer operation parameters are identical to each other. In this regard, since the read service parameters and the read customer operation parameters are different from each other (the service parameters are not reflected in the customer operation parameters), the determining unit 109 reads comparison information indicating that the read service parameters and the read customer operation parameters are different from each other. The comparison parameter includes, for example, screen information about confirmation of a change in the parameters including a warning message indicating “There are changed service parameters. Please confirm the changed service parameters on a comparison screen.” and comparison screen information.

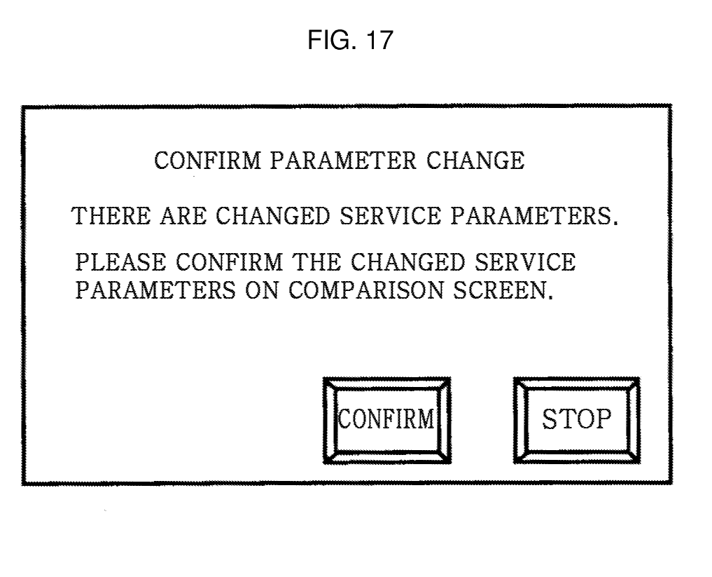

The output unit 110 outputs the screen information about confirmation of the change in the read parameters as shown in FIG. 17.

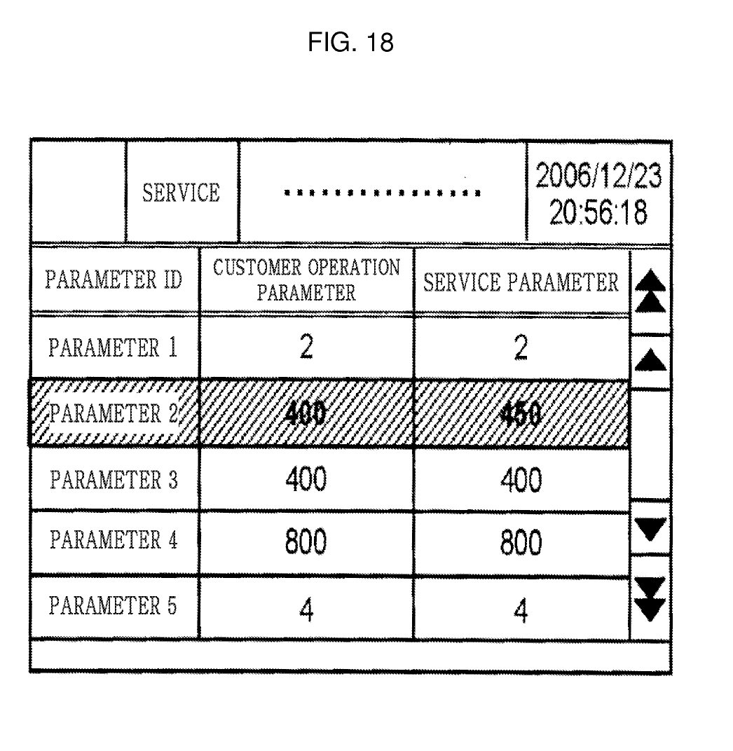

The user B presses a button “confirmation” shown in FIG. 17 and inputs a “confirmation instruction”. The input receiving unit 101 receives the confirmation instruction. The output unit 110 outputs the customer operation parameters and the service parameters read from the memory for comparison (see FIG. 18). In this regard, the output unit 110 may preferably emphasize the parameters that are different between the customer operation parameters and the service parameters. The emphasizing of the parameters includes, for example, changing the character color, font, or background of the parameters. Referring to FIG. 18, the output unit 110 emphasizes the parameters that are different between the customer operation parameters and the service parameters by changing the background of record of the parameters. The background of record of the parameters can be changed, for example, according to the comparison performed by the determining unit 109.

The user B inputs an instruction regarding an individual change with regard to a parameter 2 by using an input device (e.g., presses an individual change button by moving a focus to a row of the parameter 2) in order to reflect the changed service parameters in the customer operation parameters. The input receiving unit 101 receives the instruction regarding the individual change.

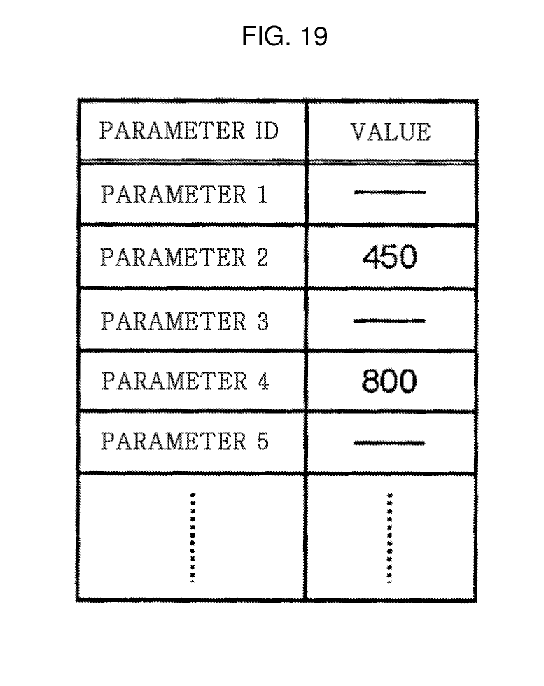

The service parameter reflecting unit 111 reads the parameter 2 “450” designated by the received instruction regarding the individual change from the service parameter storage unit 104 or memory. The service parameter reflecting unit 111 overwrites the read parameter 2 “450” with a corresponding parameter 4 stored in the customer operation parameter storage unit 103. The service parameter reflecting unit 111 obtains the customer operation parameters shown in FIG. 19.

The service parameter reflecting unit 111 deletes the parameter 2 “450” from the service parameter storage unit 104, and thus the parameter 2 stored in the service parameter storage unit 104 is null.

The user B corrects the traveling length “800” of a guide rail “parameter 4” to “780” by using an input member. The user B corrects the number “4” of cassette stages to “3” by using the input member. Then, the user B presses a button “maintenance” on an input screen.

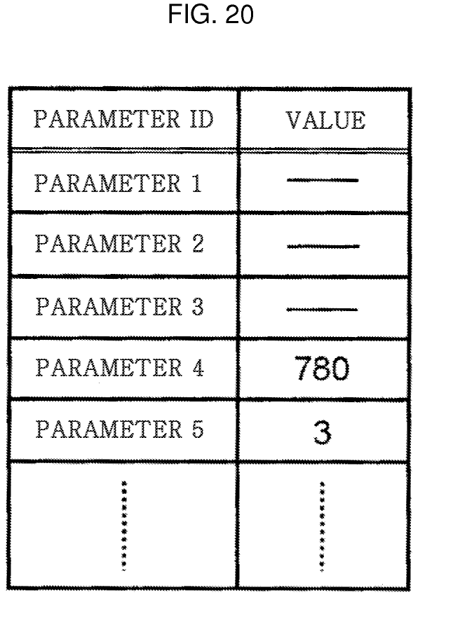

The input receiving unit 101 receives an instruction to change the apparatus operation parameters (user B inputs a value and presses the button “maintenance”). The service parameter changing unit 107 obtains two parameters (parameter 4: 780 and parameter 5: 3) according to the instruction and writes the two obtained parameters as the service parameters in the service parameter storage unit 104 shown in FIG. 20. In this regard, the customer operation parameter changing unit 106 does not usually write “3” as the parameter 5 on the customer operation parameters. In this case, a value of the parameter 5 of the customer operation parameters is read from the default parameters. However, the customer operation parameter changing unit 106 may write “3” as the parameter 5 on the customer operation parameters. That is, a parameter that is not included in the customer operation parameters, is read from the default parameters, and is written on the service parameters may be automatically reflected on the customer operation parameters.

The user B performs the semiconductor manufacturing process in order to evaluate established service parameters. That is, the user B inputs an operation instruction (presses a button for executing the semiconductor manufacturing process of the semiconductor manufacturing apparatus). Then, the input receiving unit 101 receives the operation instruction.

The processing unit 108 reads all the parameters (parameter 4: 780 and parameter 5: 3) included in the service parameters stored in the service parameter storage unit 104 and allocates the read parameter to the memory. The processing unit 108 reads a parameter (parameter 2: 450), which is not read from the parameters defined as the customer operation parameters from among the parameters that are not read from the service parameter storage unit 104, from the customer operation parameter storage unit 103 and allocates the read parameter to the memory.

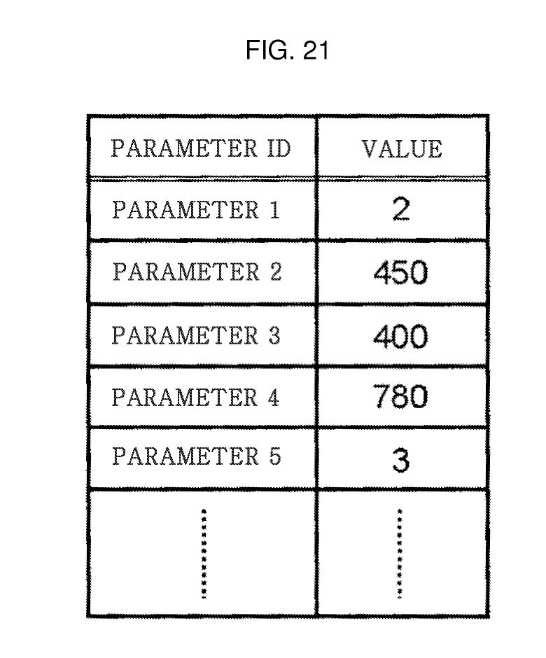

The processing unit 108 reads all parameters, which are not read from the service parameter storage unit 104 and the customer operation parameter storage unit 103, from the parameters stored in the default parameter storage unit 102. Therefore, the apparatus operation parameters shown in FIG. 21 are obtained. The processing unit 108 executes the semiconductor manufacturing process according to the apparatus operation parameters shown in FIG. 21. As described above, the semiconductor manufacturing process is performed in the mode 2 that is the service mode. The user B examines a manufacturing result to determine whether the established customer operation parameters are satisfactory or not. In this regard, the service parameters established by the use B are more preferable for completely manufacturing an excellent semiconductor.

The user B inputs an instruction to output the changed service parameters. The output unit 110 reads the changed service parameters (parameter 4: 780 and parameter 5: 3) from the service parameter storage unit 104. The output unit 110 outputs the read service parameters (parameter 4: 780 and parameter 5: 3) onto the display.

The user B inputs an instruction regarding a complete change (e.g., presses a whole change button) by using the input member. The input receiving unit 101 receives the instruction regarding the complete change.

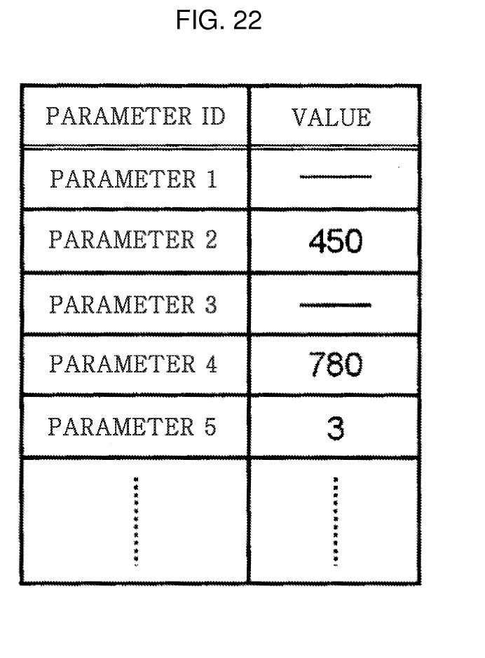

In response to the receipt of the instruction regarding the complete change, the service parameter reflecting unit 111 reads all parameters (parameter 4: 780 and parameter 5: 3) included in the service parameters from the service parameter storage unit 104 or memory. The service parameter reflecting unit 111 overwrites the value “780” of the read parameter 4 and the value “3” of the read parameter 5 with the corresponding parameter 4 stored in the customer operation parameter storage unit 103. The service parameter reflecting unit 111 obtains the customer operation parameters shown in FIG. 22.

The service parameter reflecting unit 111 deletes the value “780” of the parameter 4 and the value “3” of the parameter 5 from the service parameter storage unit 104, and thus the parameters 4 and 5 stored in the service parameter storage unit 104 are null.

In this regard, if the service parameters are reflected in the customer operation parameters, the original customer operation parameters may be restored at any time by removing them from the memory.

According to the present embodiment, a service engineer who logs in to the semiconductor manufacturing apparatus in the second mode may maintain or evaluate the semiconductor manufacturing apparatus and reflect the service parameters in the customer operation parameters.

According to the present embodiment, the service engineer may not necessarily adjust the service parameters and a customer may not necessarily adjust the customer operation parameters. Therefore, according to the present embodiment, two or more different users who log in to the semiconductor manufacturing apparatus in two or more different modes can individually adjust the apparatus operation parameters.

According to the present embodiment, data of the service parameters and the customer operation parameters may be secured in various ways. Differences between the default parameters are maintained as the customer operation parameters. Differences between the customer operation parameters are maintained as the service parameters. However, the customer operation parameters are a parameter group having the same data structure as the service parameters and may be defined as a different parameter group from the service parameters. In this case, for example, initially (at the shipping of the semiconductor manufacturing apparatus or at an initial start thereof), each value of the parameter group of the default parameters is copied on the customer operation parameters and the service parameters. The service engineer adjusts the service parameters and inputs various types of instructions into the semiconductor manufacturing apparatus of the service engineer. The semiconductor manufacturing apparatus may or may not reflect adjusted (changed) values of the service parameters in the customer operation parameters according to whether various types of instructions are input or not.

According to the present embodiment, when the service engineer changes the service parameters, the service engineer inputs an instruction regarding a complete change or an instruction regarding an individual change so that the semiconductor manufacturing apparatus reflects changed values of the parameters as values of the parameters included in the customer operation parameters. However, when the service engineer changes the service parameters, if the semiconductor manufacturing apparatus reflects the changed values of the parameters as the values of the parameters included in the customer operation parameters and thus, the service engineer inputs an instruction (to cancel the change in the service parameters) to restore the original values of the parameters, the changed values of the parameters may not be reflected in the customer operation parameters. In this case, when the service engineer changes the service parameters, a structure is required in which the customer operation parameters are simultaneously changed and the original values of the customer operation parameters are backed up. The structure, for example, may be a management method (may be a version management method) of recording the customer operation parameters, before they are corrected, into another file, when the customer operation parameters are corrected.

According to the present embodiment, for example, the customer operation parameters and the service parameters may be converted and displayed according to a user's instructions. Such a conversion is effective when it is impossible to compare the customer operation parameters with the service parameters due to a small display area.

The processing of the present embodiment may be realized by using software. The software may be downloaded and distributed. The software may be recorded on a recording medium such as CD-ROM and be circulated. These may be applied to other embodiments of the present invention. The software used to realize the semiconductor manufacturing apparatus of the present embodiment is a program which makes a computer operate as an input receiving unit that receives an input regarding login in a first mode, an input regarding login in a second mode, and an input regarding a change in apparatus operation parameters that are one or more parameters used to operate the semiconductor manufacturing apparatus, a login processing unit that, when the input receiving unit receives the input regarding login in the first mode, processes login in the first mode, when the input receiving unit receives the input regarding login in the second mode, processes login in the second mode, a customer operation parameter changing unit that, when the input receiving unit receives the input regarding the change in the apparatus operation parameters from a user who logs in to the semiconductor manufacturing apparatus in the first mode, changes the customer operation parameters that are the apparatus operation parameters that can be changed by an input of the user who logs in to the semiconductor manufacturing apparatus in the first mode, a service parameter changing unit that, when the input receiving unit receives the input regarding the change in the apparatus operation parameters from a user who logs in to the semiconductor manufacturing apparatus in the second mode, changes the service parameters that are the apparatus operation parameters that can be changed by an input of the user who logs in to the semiconductor manufacturing apparatus in the second mode, a processing unit that reads at least the customer operation parameters or the service parameters stored in a recording medium and performs an operation for executing a semiconductor manufacturing process according to the read parameters, a determining unit that compares the customer operation parameters with the service parameters and determines whether the customer operation parameters and the service parameters are identical to each other, and an output unit that, when the determining unit determines that the customer operation parameters and the service parameters are different from each other, outputs comparison information indicating that the customer operation parameters and the service parameters are different from each other.

The program may preferably operate the processing unit to read at least default parameters that are the apparatus operation parameters at default, the customer operation parameters, or the service parameters and execute the semiconductor manufacturing process according to the read parameters.

The program may preferably operate the input receiving unit to receive an instruction to output changed service parameters, and, when the input receiving unit receives the instruction to output changed service parameters, and operate the output unit to read the service parameters changed by the service parameter changing unit stored in the recording medium and to output the read changed service parameters, instead of outputting the comparison information.

The comparison information may be preferably information including the customer operation parameters and the service parameters.

The program may preferably operate the input receiving unit to receive a complete change instruction to completely overwrite the service parameters with the customer operation parameters or an individual change instruction to individually overwrite the service parameters with the customer operation parameters, and makes the computer additionally operate as a service parameter reflecting unit that, when the input receiving unit receives the complete change instruction, completely overwrites the service parameters with the customer operation parameters, or when the input receiving unit receives the individual change instruction, individually overwrites parameters corresponding to the service parameters according to the corresponding individual change instruction with parameters corresponding to the customer operation parameters.

The program may preferably operate the processing unit to read the service parameters stored in the recording medium, read the customer operation parameters corresponding to parameters that are not defined as the corresponding service parameters stored in the recording medium, and perform an operation for executing the semiconductor manufacturing process according to the read parameters.

The program may preferably operate the processing unit to read the service parameters stored in the recording medium, read the customer operation parameters corresponding to parameters that are not defined as the corresponding service parameters stored in the recording medium, read the default parameters corresponding to parameters that are not defined as the corresponding service parameters or customer operation parameters stored in the recording medium, and perform the operation for executing the semiconductor manufacturing process according to the read parameters.

The operation for executing the semiconductor manufacturing process may be processed by using, for example, software to send data to hardware that executes the semiconductor manufacturing process.

In the above embodiments, each process (each function) may be performed by a single device (system) or may be performed by a plurality of devices.

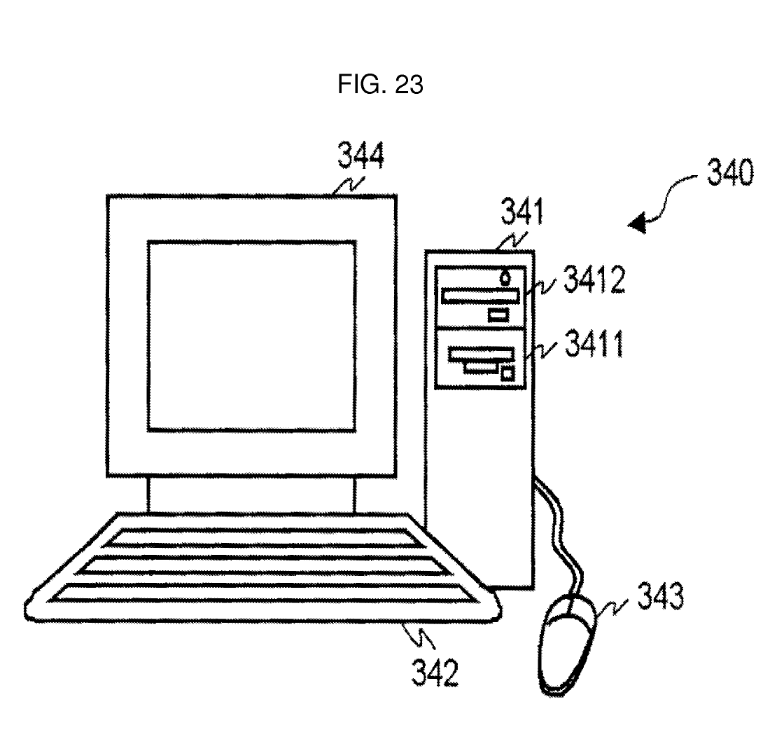

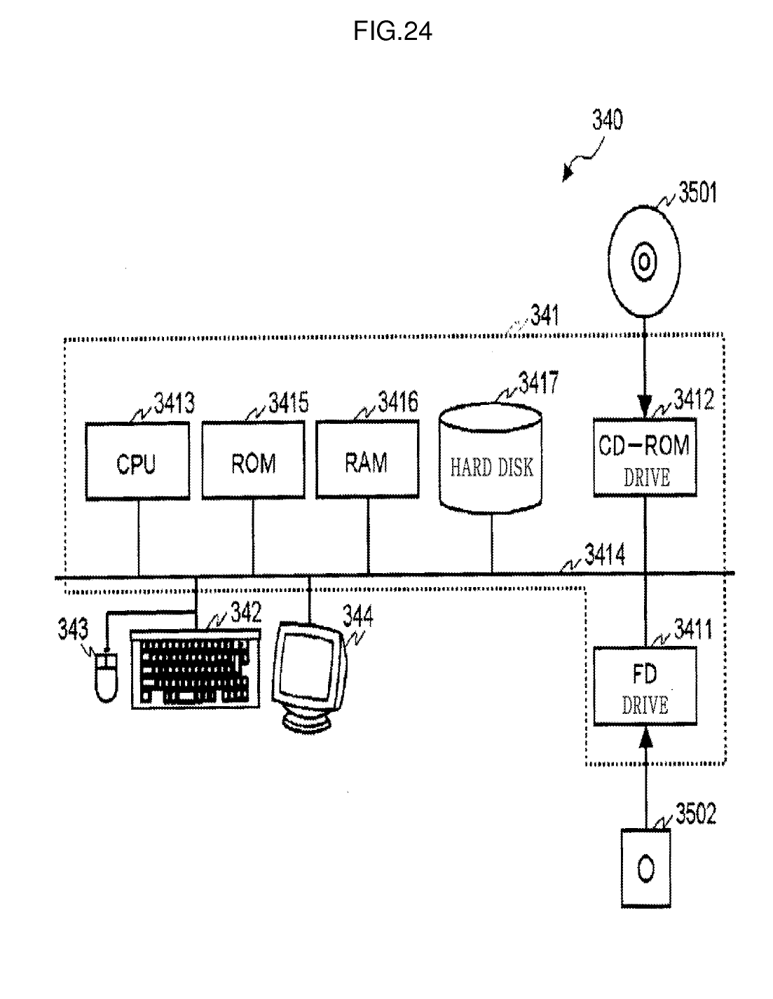

FIG. 23 is a view showing the appearance of a computer system 340 that executes the program described above for realizing the semiconductor manufacturing apparatus of the embodiments described above. The embodiments described above may be realized by using computer hardware and a computer program executed therein. FIG. 23 shows an overview of the computer system 340. FIG. 24 is a block diagram of the computer system 340.

Referring to FIG. 23, the computer system 340 includes a computer 341 including a flexible disk (FD) drive 3411 and a CD-ROM drive 3412, a keyboard 342, a mouse 343, and a monitor 344.

Referring to FIG. 24, the computer 341 includes, in addition to the FD drive 3411 and the CD-ROM drive 3412, a CPU 3413, a bus 3414 that is connected to the FD drive 3411 and the CD-ROM drive 3412, a ROM 3415 for storing a boot-up program, a RAM 3416 that is connected to the CPU 111, which temporarily stores instructions of an application program and provides a temporal storage space, a hard disk 3417 that stores the application program, a system program, and data. The computer 341 may further include a network card (not shown) used to connect a local area network (LAN).

A program for executing a function of the semiconductor manufacturing apparatus may be stored in a CD-ROM 3501 or an FD 3502, may be inserted into the CD-ROM drive 3412 or the FD drive 3411, and may be transmitted to the hard disk 3417. Alternatively, the program may be transmitted to the computer 341 over a network (not shown) and be stored in the hard disk 3417. The program may be loaded in the RAM 3416 when executed. The program may be directly loaded from the CD-ROM 3501, the FD 3502, or the network.

The program may or may not include an operating system (OS) for executing the function of the semiconductor manufacturing apparatus or a third party program in the computer 341. The program may include an instruction unit used to obtain a desired result by using a properly controlled function (module). The operation of the computer system 340 is well known and thus a detailed description thereof will not be given here.

A single computer or a plurality of computers may execute the program. That is, the program may be executed unitarily or separately.

As described above, according to the semiconductor manufacturing apparatus of the present invention, two or more different users that log in to the semiconductor manufacturing apparatus in two or more different modes individually control apparatus operation parameters, thereby operating the semiconductor manufacturing apparatus at higher performance.

The disclosure of the detailed description, the claims, and the drawings of Japanese Patent Application No. 2007-078013 filed on Mar. 24, 2007, in the Japanese Patent Office, is incorporated herein in its entirety by reference.

As described above, the semiconductor manufacturing apparatus according to the present invention has an effect that two or more users who logged into the semiconductor manufacturing in two or more different modes can individually control the apparatus operation parameter. Thus, it is possible to more efficiently operate the semiconductor manufacturing apparatus.

While this invention has been particularly shown and described with reference to exemplary embodiments thereof, it will be understood by those of ordinary skill in the art that various changes in form and details may be made therein without departing from the spirit and scope of the invention as defined by the appended claims.

What is claimed is:

1. A semiconductor manufacturing apparatus for performing a semiconductor manufacturing process, the apparatus comprising:
an input receiving unit for receiving an input regarding login in a first mode, an input regarding login in a second mode, and an input regarding a change in apparatus operation parameters that comprise one or more parameters used to operate the semiconductor manufacturing apparatus;
a customer operation parameter storage unit for storing customer operation parameters that comprise apparatus operation parameters that are changeable by an input of a user who logs in to the semiconductor manufacturing apparatus in the first mode;
a service parameter storage unit for storing service parameters that comprise apparatus operation parameters that are changeable by an input of a user who logs in to the semiconductor manufacturing apparatus in the second mode;
a login processing unit for, when the input receiving unit receives the input regarding login in the first mode, processing login to the semiconductor manufacturing apparatus in the first mode, and when the input receiving unit receives the input regarding login in the second mode, processing login to the semiconductor manufacturing apparatus in the second mode;
a customer operation parameter changing unit for, when the input receiving unit receives the input regarding the change in the apparatus operation parameters from the user who logs in to the semiconductor manufacturing apparatus in the first mode, changing the customer operation parameters stored in the customer operation parameter storage unit;
a service parameter changing unit for, when the input receiving unit receives the input regarding the change in the apparatus operation parameters from the user who logs in to the semiconductor manufacturing apparatus in the second mode, changing the service parameters stored in the service parameter storage unit;
a processing unit for reading at least the customer operation parameters or the service parameters and performing an operation for executing the semiconductor manufacturing process according to the read parameters;
a determining unit for comparing the customer operation parameters with the service parameters and determining whether the customer operation parameters and the service parameters are identical to each other; and
an output unit for, if the determining unit determines that the customer operation parameters and the service parameters are different from each other, outputting comparison information indicating that the customer operation parameters and the service parameters are different from each other.

2. The apparatus of claim 1, further comprising:
a default parameter storage unit for storing default parameters that comprise default apparatus operation parameters,
wherein the processing unit reads at least the default parameters, the customer operation parameters, or the service parameters and performs the operation for executing the semiconductor manufacturing process according to the read parameters.

3. The apparatus of claim 1, wherein the input receiving unit further receives an instruction to output changed service parameters; and
wherein, when the input receiving unit receives the instruction to output the changed service parameters, the output unit reads the service parameters changed by the service parameter changing unit from the service parameter storage unit and outputs the read changed service parameters, instead of outputting the comparison information.

4. The apparatus of claim 1, wherein the comparison information includes the customer operation parameters and the service parameters.

5. The apparatus of claim 1, wherein the input receiving unit further receives a complete change instruction to completely overwrite the service parameters with the customer operation parameters or an individual change instruction to individually overwrite the service parameters with the customer operation parameters,
the apparatus further comprising:
a service parameter reflecting unit for, when the input receiving unit receives the complete change instruction, completely overwriting the service parameters with the customer operation parameters, or when the input receiving unit receives the individual change instruction, individually overwriting parameters corresponding to the service parameters according to the corresponding individual change instruction with parameters corresponding to the customer operation parameters.

6. The apparatus of claim 1, wherein the processing unit:
reads the service parameters from the service parameter storage unit;
for parameters that are not defined as the service parameters, reads the corresponding customer operation parameters from the customer operation parameter storage unit; and
performs the operation for executing the semiconductor manufacturing process according to the read parameters.

7. The manufacturing apparatus of claim 2, wherein the processing unit:
reads the service parameters from the service parameter storage unit;
for parameters that are not defined as the service parameters, reads the corresponding customer operation parameters from the customer operation parameters;
for parameters that are not defined as the service parameters nor the customer operation parameters, reads the corresponding default parameters from a default parameter storage unit; and
performs the operation for executing the semiconductor manufacturing process according to the read parameters.

8. A method of managing apparatus operation parameters executed by an input receiving unit, a login processing unit, a customer operation parameter changing unit, a service parameter changing unit, a processing unit, a determining unit, and an output unit, the method comprising:
an input receiving step of receiving an input regarding login in a first mode, an input regarding login in a second mode, and an input regarding a change in apparatus operation parameters that comprise one or more parameters used to operate the semiconductor manufacturing apparatus, wherein the input receiving unit performs the input receiving step;
a login processing step, when the input regarding login in the first mode is received in the input receiving step, of processing login to the semiconductor manufacturing apparatus in the first mode, and when the input regarding login in the second mode is received in the input receiving step, of processing login to the semiconductor manufacturing apparatus in the second mode, wherein the input receiving unit performs the login processing step;
a customer operation parameter changing step, when the input regarding the change in the apparatus operation parameters is received from a user who logs in to the semiconductor manufacturing apparatus in the first mode in the input receiving step, of changing the customer operation parameters that comprise the apparatus operation parameters that are changeable by an input of the user who logs in to the semiconductor manufacturing apparatus in the first mode, wherein the customer operation parameter changing unit performs the customer operation parameter changing step;
a service parameter changing step, when the input regarding the change in the apparatus operation parameters is received from a user who logs in to the semiconductor manufacturing apparatus in the second mode in the input receiving step, of changing the service parameters that are changeable by an input of the user who logs in to the semiconductor manufacturing apparatus in the second mode, wherein the service parameter changing unit performs the service parameter changing step;
a processing step of reading at least the customer operation parameters or the service parameters stored in a recording medium and performing an operation for executing a semiconductor manufacturing process according to the read parameters, wherein the processing unit performs the processing step;
a determining step of comparing the customer operation parameters with the service parameters and determining whether the customer operation parameters and the service parameters are identical to each other, wherein the determining unit performs the determining step; and
an outputting step, if it is determined that the customer operation parameters and the service parameters are different from each other in the determining step, of outputting comparison information indicating that the customer operation parameters and the service parameters are different from each other, wherein the output unit performs the outputting step.

9. The method of claim 8, wherein, in the processing step, at least default parameters that comprise default apparatus operation parameters, the customer operation parameters, or the service parameters are read from the recording medium and the operation for executing the semiconductor manufacturing process is performed according to the read parameters.

10. A program which makes a computer operate as:
an input receiving unit for receiving an input regarding login in a first mode, an input regarding login in a second mode, and an input regarding a change in apparatus operation parameters that comprise one or more parameters used to operate the semiconductor manufacturing apparatus;
a login processing unit for, when the input receiving unit receives the input regarding login in the first mode, processing login to the semiconductor manufacturing apparatus in the first mode, and when the input receiving unit receives the input regarding login in the second mode, processing login to the semiconductor manufacturing apparatus in the second mode;
a customer operation parameter changing unit for, when the input receiving unit receives the input regarding the change in the apparatus operation parameters from a user who logs in to the semiconductor manufacturing apparatus in the first mode, changing the customer operation parameters that comprise the apparatus operation parameters that are changeable by an input of the user who logs in to the semiconductor manufacturing apparatus in the first mode;
a service parameter changing unit for, when the input receiving unit receives the input regarding the change in the apparatus operation parameters from a user who logs in to the semiconductor manufacturing apparatus in the second mode, changing the service parameters that are the apparatus operation parameters that are changeable by an input of the user who logs in to the semiconductor manufacturing apparatus in the second mode;
a processing unit for reading at least the customer operation parameters or the service parameters stored in a recording medium and performing an operation for executing the semiconductor manufacturing process according to the read parameters;
a determining unit for comparing the customer operation parameters with the service parameters and determining whether the customer operation parameters and the service parameters are identical to each other; and
an output unit for, if the determining unit determines that the customer operation parameters and the service parameters are different from each other, outputting comparison information indicating that the customer operation parameters and the service parameters are different from each other.

11. The program of claim 10, wherein, the processing unit reads at least default parameters that comprise default apparatus operation parameters, the customer operation parameters, or the service parameters from the recording medium and performs the operation for executing the semiconductor manufacturing process according to the read parameters.
